(19) United States
(12) Patent Application Publication
(10) Pub. No.: US 2011/0085287 A1
(43) Pub. Date: Apr. 14, 2011

(54) MODULAR SYSTEM WITH APPLIANCE AND COVER HAVING ANTENNA

(75) Inventors: Matthew P. Ebrom, Holland, MI (US); Wallace J. Elston, Paw Paw, MI (US); Anthony E. Jenkins, Covert, MI (US); Gregory S. Lieto, Grand Haven, MI (US); Richard A. McCoy, Stevensville, MI (US); Michael A. Morrell, Hudsonville, MI (US); Peter J. Richmond, Berrien Springs, MI (US)

(73) Assignee: WHIRLPOOL CORPORATION, Benton Harbor, MI (US)

(21) Appl. No.: 12/904,427

(22) Filed: Oct. 14, 2010

Related U.S. Application Data
(60) Provisional application No. 61/251,324, filed on Oct. 14, 2009.

(51) Int. Cl. H05K 7/00

(52) U.S. Cl. 361/679.01

(57) ABSTRACT

A modular system comprises an appliance having a visible surface, a first service interface positioned on the visible surface, a cover detachably coupled to the visible surface and disposed to overlie the first service interface, a controller configured to selectively provide operational instructions to the appliance and/or the cover, and an antenna provided within the cover and operably connected to the controller.

### CROSS REFERENCE TO RELATED APPLICATION

The present application claims the benefit of U.S. Provisional Patent Application No. 61/251,324, filed Oct. 14, 2009, which is incorporated herein by reference in its entirety.

### BACKGROUND INFORMATION

Many homes include one or more household appliances, such as washing machines, clothes dryers, ovens, dishwashers, refrigerators, freezers, microwave ovens, and the like. Consumers increasingly expect additional functionality for these appliances, and appliance manufacturers are looking for new and innovative ways to provide appliances with such additional functionality. For example, manufacturers are often providing appliances with an ever-expanding array of features. While expanding the functionality of appliances, manufacturers are also working to ensure that their products are aesthetically pleasing.

Appliances are typically provided with a nameplate to visually display a logo for the appliance. These nameplates are often displayed prominently on a normally visible surface of the appliance, such as on a door, a console, a backsplash, or front surface of the appliance. However, these nameplates are intended to be non-removable by the user, and do not perform any useful function beyond visually displaying a logo.

### SUMMARY

According to one embodiment of the invention, a modular system comprises an appliance having a visible surface and configured to selectively perform a physical operation on an article, a first service interface positioned on the visible surface and configured to provide a service, a cover detachably coupled to the visible surface and disposed to overlie the first service interface, a controller configured to selectively provide operational instructions to one of the appliance and the cover, and an antenna provided within the cover and operably connected to the controller.

The present invention will be more fully understood upon reading the following detailed description in conjunction with the accompanying drawings.

### BRIEF DESCRIPTION OF THE DRAWINGS

In the drawings:

FIG. 1 is a perspective view of a modular system according to a first embodiment of the invention, comprising an appliance and a badge.

FIG. 2 is a front view of the modular system of FIG. 1, with a door of the appliance open.

FIG. 3 is a schematic illustration of the modular system of FIG. 1, showing the badge and a service interface.

FIG. 4 is a close-up, exploded perspective view of the modular system of FIG. 1, showing the badge and the service interface.

FIG. 5 is a sectional side view of the modular system of FIG. 1 taken along line 5-5 of FIG. 4.

FIG. 6 is a close-up, exploded perspective view of the modular system of FIG. 1, showing a second badge and a second service interface.

FIG. 7 is a close-up, exploded perspective view of a modular system according to a second embodiment of the invention, comprising an appliance, a badge and a service interface.

FIG. 8 is a sectional side view of the modular system of FIG. 7 taken along line 8-8 of FIG. 7.

FIG. 9 is a rear view of the badge from FIG. 7.

FIG. 10 is sectional side view of a modular system according to a third embodiment of the invention, illustrating a badge pivotally attached to an appliance proximate to a service interface.

FIG. 11 is sectional side view of a modular system according to a fourth embodiment of the invention, illustrating a badge removably attached to an appliance proximate to a service interface by spring-loaded insertion pins.

FIG. 12 is sectional side view of a modular system according to a fifth embodiment of the invention, illustrating a badge screwably attached to an appliance proximate to a service interface.

FIG. 13 is sectional side view of a modular system according to a sixth embodiment of the invention, illustrating a badge removably attached to an appliance proximate to a service interface by a mechanical connection.

FIG. 14 is sectional side view of a modular system according to a seventh embodiment of the invention, comprising an appliance, a badge, a service interface, and an accessory.

FIG. 15 is a perspective view of the badge and the accessory from FIG. 14.

FIG. 16 is a rear view of the badge from FIG. 14.

FIG. 17A is a partially-exploded perspective view of a modular system according to an eighth embodiment of the invention comprising an appliance, a badge having at least one antenna, and a service interface.

FIG. 17B is a close-up, exploded perspective view of FIG. 17A.

FIG. 18 is a front view of the badge from the modular system of FIG. 17A.

FIG. 19 is an exploded perspective view of a modular system according to a ninth embodiment of the invention comprising an appliance having an antenna, a badge, and a service interface.

FIG. 20 is a side view of the modular system from FIG. 19, showing a wireless signal propagation pattern of the antenna.

FIG. 21 is a top view of a modular system according to a tenth embodiment of the invention comprising an appliance having an antenna with a wireless signal propagation pattern.

FIG. 22 is a top view of a modular system according to an eleventh embodiment of the invention comprising an appliance having multiple antennas with wireless signal propagation patterns.

FIG. 23 is sectional side view of a modular system according to a twelfth embodiment of the invention, comprising an appliance having an antenna and power source, a badge, a service interface, and an accessory, with the badge in an open position and the accessory decoupled from the service interface.

FIG. 24 is sectional side view of the modular system from FIG. 23, with the badge in a closed position and the accessory coupled to the service interface.

FIG. 25 is a flow diagram according to a thirteenth embodiment of the invention showing a process for promoting the purchase of an accessory.

### DETAILED DESCRIPTION OF PREFERRED EMBODIMENTS

The invention relates generally to a system including an appliance and a cover for the appliance. Illustrative approaches to the disclosed systems and methods are shown in detail in the drawings and described below. Although the drawings represent some possible approaches, the drawings are not necessarily to scale and certain features may be exaggerated, removed, or partially sectioned to better illustrate and explain the embodiments. Further, the descriptions set forth herein are not intended to be exhaustive or to otherwise limit or restrict the claims to the precise forms and configurations shown in the drawings and disclosed in the following detailed description.

The following definitions apply to terms that may be used in the specification and the claims, unless otherwise noted.

An “appliance” is a machine that performs a physical operation by performing a useful cycle of operation. An appliance may, for example, be a household or kitchen appliance, such as a refrigerator, that performs a cooling cycle and/or an ice-making cycle. Other non-limiting examples of an appliance are a freezer, a stove, an oven, a range, a microwave, a dishwasher, a clothes washing machine, a clothes dryer, a clothes refreshing machine, a non-aqueous washing apparatus, an air conditioner, a dehumidifier, or any combination thereof.

A “service” is a useful functionality that may be communicated from one device to another device. Examples of a service include, but are not limited to, electrical power, data, mechanical power, mechanical motion, thermal energy, illumination, sound or acoustic, fluid power, or a substance. An electrical service may include both electrical power and data. A service may comprise multiple categories of service, such as electrical power and data in a single signal. A service may be provided continuously, for specified times, for specified amounts, or for the duration of certain events, such as the duration of coupling to provide timed dispensing. Alternatively, a service may be provided in quanta, such as packets of data, doses of substance, batches of discrete items such as tablets, or consumable components. The term “service” does not include mechanical coupling or attachment without power or motion transfer.

“Electrical power communication” is the coupling of two devices to supply electrical power from at least one of the devices to the other of the devices, such as through directly connected electronic lines or through wireless power communication (also referred to as wireless power transmission). Wireless power communication can include any type of wireless power communication, including, but not limited to, microwave transmission, laser transmission, and magnetic fields. Exemplary categories of electrical power communication include the type of power, e.g. alternating current (also known as AC) or direct current (also known as DC), supplied to the device and variations in the characteristics of the power, such as the voltage or current.

“Data communication” is the coupling of two devices to transmit data from at least one of the devices to the other of the devices, such as through directly connected electronic lines or through wireless data communication (also referred to as wireless data transmission). The data may be transmitted as a separate signal or embedded in electrical power communication. Wireless data communication can include any type of wireless data communication, including, but not limited to, wireless network (a/k/a Wi-Fi), radio transmission, light transmission, acoustical transmission, and other wave-based and signal-based information transmission vehicles. Exemplary categories of data communication include encrypted and unencrypted data. Data communication also includes communication for different protocols, including physical layer protocols and software layer protocols. Examples of physical layer protocols are a wired Ethernet and a wireless (Wi-Fi) network, both of which may support the same data packet structure. Examples of software layer protocol are ZigBee and Bluetooth. Data communication may also be completed by way of an analog mechanical transmission means, such as by means of fluidic pulses created by positive pressure systems, vacuum systems, or by a mechanical logic transfer means, such as the throwing of switches or levers to actuate or transmit information about a control state.

“Mechanical power communication” is the coupling of two devices to supply mechanical power from at least one of the devices to the other of the devices, such as through the transfer of mechanical motion through the coupling of rotating members.

“Thermal energy communication” or “heat communication” is the coupling of two devices to transmit thermal energy from at least one of the devices to the other of the devices, such as through delivery of a fluid through a line between the devices. Thermal energy communication includes cooling as well as heating.

“Substance communication” is the coupling of two devices to transmit a substance from at least one of the devices to the other of the devices, such as through delivery of a fluid through a line between the objects. Examples of substances include, but are not limited to, liquid soap, powdered soap, compressed air, tablets, caplets, water, ice cubes, a beverage, as well as others.

“Illumination communication” is the coupling of two devices to supply illumination from at least one of the devices to the other of the devices, such as through the coupling of two light pipes or a light transmitter and receiver combination such as opto-isolator.

The term “consumable” and any variation thereof, as used herein, includes any substance that may be consumed by a host, an accessory device, or a user person, such as food, cosmetics, or medicine. The consumable may, for example, be a substance that is used up and must be replenished for subsequent cycles of operation. For a clothes washer, a consumable might be a detergent and/or a softener. For a clothes dryer, a consumable might be an anti-static cloth. For a cooking or refrigeration appliance, the consumable may actually be the article on which the appliance performs its cycle of operation, as in the case of food, later to be consumed by a person. More specific examples of the use of a consumable in appliances include dispensing additives for clothes washers, clothes dryers, or combination washer/dryer appliances. The additives may include, but are not limited to, normal detergents, gentle detergents, dark clothing detergents, cold water detergents, fabric softeners, chlorine bleaches, color-safe bleaches, and fabric enhancement chemistry. Non-limiting examples of fabric enhancers are additives to provide stain resistance, wrinkle resistance, water repellency, insect repellency, color fastness, fragrances, and anti-microbials. Another example of a consumable is the filter used by an appliance. Refrigerators, dryers, washers, and dishwashers are all known to use filters that are consumed in the sense that they wear out and must be replaced.

A “service interface” is an interface capable of cooperating with another interface to facilitate the communication of a service therebetween.

A “service connector” as used herein is a connector component of a service interface. A service connector will cooperate with one another service connector to facilitate the communication of a service between the service interfaces. A single service connector may carry multiple services.

As used herein, an “accessory” is a device that may be used primarily in conjunction with an appliance to enhance, supplement, regulate or monitor the functionality of the appliance. An accessory may be mechanically mounted or otherwise physically coupled to the appliance. Examples of an accessory include, but are not limited to, a water filter, a water purifier, an air purifier, a sensor, a light source, a speaker a motion detector, a transceiver, a wireless transceiver, a microcontroller, a processor, a dispenser, a network interface adapter, a memory, and any combination thereof. An accessory can further include more than one sensor, such as a water-quality sensor, an air-quality sensor, a power measurement sensor, or any combination thereof.

A “badge” is a cover associated with an appliance or an accessory for an appliance that includes indicia. Non-limiting examples of the indicia can be a message, a logo, or some other ornamental trigger configured to invoke an emotional response. The indicia may be related to the model, brand, retailer, or manufacturer of the appliance or the accessory. The indicia may be associated with the appliance fit, form, finish, or performance. More than one indicia can be provided on a single badge. The indicia may vary, such as being provided by an electronic display and varying based on input from the appliance or the accessory. The indicia may communicate a status of the appliance, accessory, or the badge itself. For example, if the accessory is a water filter, the badge may communicate when it is time to dispose the water filter and get a new one. The badge can provide an aesthetically pleasing appearance in addition to useful information, such as by having a coherent or matching appearance with the appliance or accessory, or by having a particular design scheme using various colors, textures, or surface patterns.

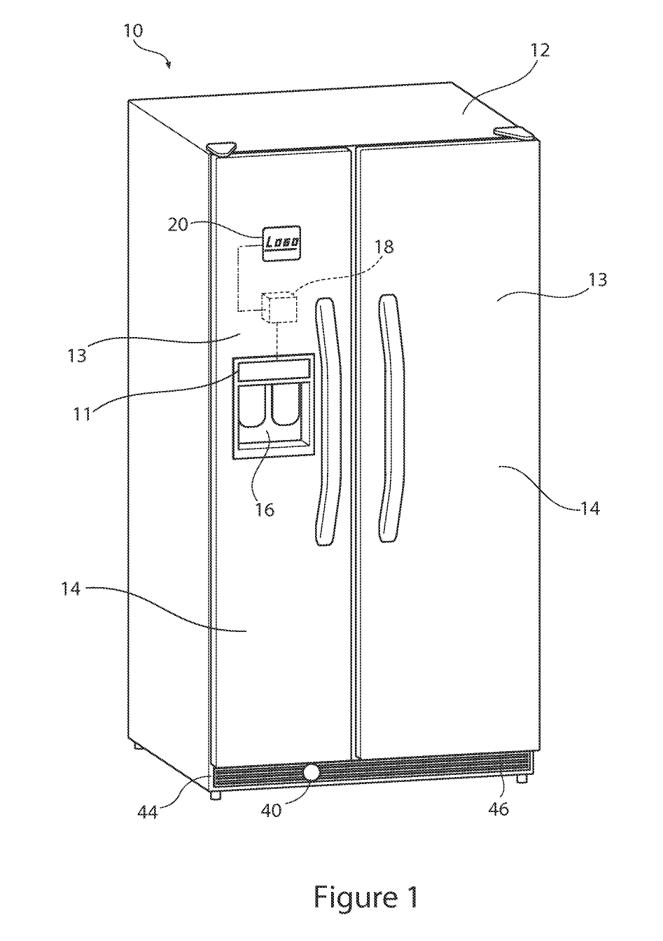

Referring now to the drawings, FIG. 1 illustrates an appliance 10 having a badge 20 according to a first embodiment of the invention. Appliance 10 generally performs such a physical operation on an article by performing a useful cycle of operation. Appliance 10 typically includes one or more cavities for selectively receiving an article. For example, a refrigerator or an oven typically includes one or more cavities for selectively receiving food, and a washing machine or dryer typically includes one or more cavities for selectively receiving clothing. A cavity may be disposed within a cabinet that is accessible by way of a drawer, a pivotal door, a sliding door, or a door otherwise attached, such as via snaps, screws, bolts, vices, grippers, adhesives, hook-and-loop fastener material, or magnetic attraction. Moreover, the cavity may be accessible by a door that can be embodied by the badge 20 itself.

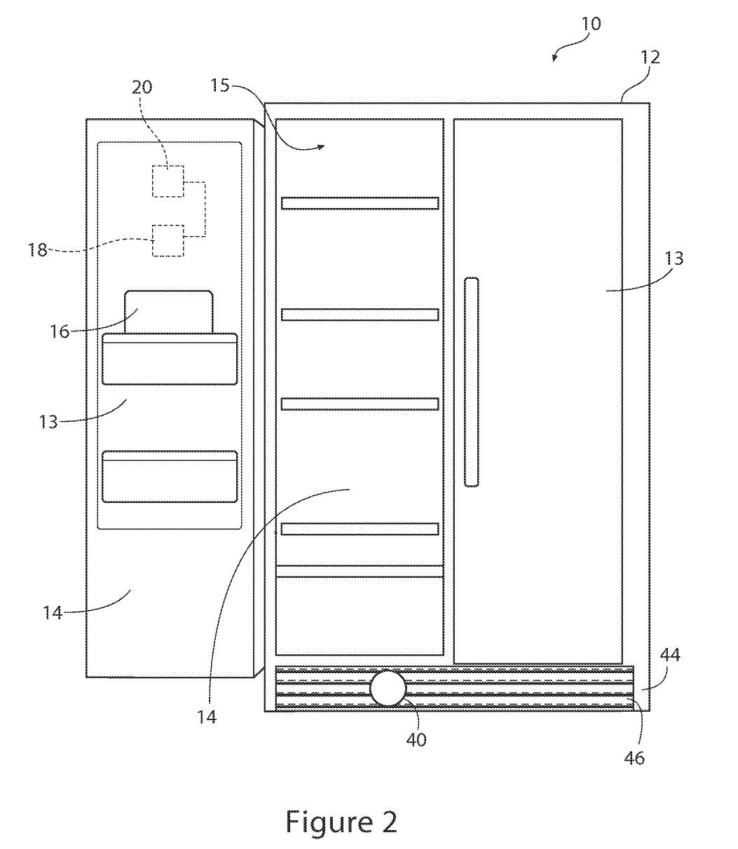

For example, as illustrated in FIGS. 1 and 2, appliance 10 can be a household refrigerator that can provide a controlled environment for storing food, and can perform a cooling cycle, a water filtration cycle, and/or an ice-making cycle. Appliance 10 has a cabinet or body 12 that includes a cavity 15 configured to selectively receive an article. Appliance 10 may also include one or more door(s) 13 moveably mounted to the body 12 and configured to selectively provide access to the cavity 15.

Appliance 10 may take on many different shapes and sizes, and may be placed in any number of different orientations, but typically includes at least one visible surface. Appliance 10 is typically located in a room of a house, such as a kitchen or a laundry room, and at least one face or surface of appliance 10 is typically in plain view of a person standing in the room, and is considered to be a visible surface. For example, appliance 10 may be a household refrigerator that is placed in a kitchen such that the front of appliance 10 is not only in plain view, but easily accessible. A visible surface may be located either on an exterior portion of appliance 10, or an interior surface, such as those surfaces that define an interior cavity, such as cavity 15. To ensure an aesthetically pleasing appearance, at least one exterior surface of appliance 10 can be a visible surface.

In the embodiment illustrated in FIGS. 1 and 2, appliance 10 includes a visible surface 14 on the exterior front surface of the door 13 and a visible surface 14 on the interior surface of the door 13. Further, cavity 15 of appliance 10 may also include a visible surface 14 that is in plain view when the door 13 is open.

Visible surface 14 typically provides appliance 10 with a finished look, and may include one or more colors and/or textures. For example, appliance 10 may be a household refrigerator that includes multiple interior visible surfaces 14, such as interior doors, shelves, and an exterior surface that may include a user interface panel, a water filter container, etc. Visible surface 14 is typically plastic or metal, and may utilize one or more of the following coverings: paint, enamel, colored material, metal, plastic, stainless steel, paneling, or the like to provide a desirable appearance.

Badge 20 may be disposed on a visible surface 14, as will be discussed in greater detail below. Further, appliance 10 may also include a user interface or a control panel 11, an ice/water dispenser 16, or some other feature or device disposed on visible surface 14.

Certain features of appliance 10, such as the user interface or control panel 11, are often connected to a controller 18. Controller 18 generally controls one or more cycles of operation, and may communicate with the user interface or control panel 11. Controller 18 may include one or more microcontrollers, processors, memory, computer readable mediums, and I/O ports used to manage a cycle of operation and/or communicate with other components, electronic devices, etc. For example, appliance 10 may be a refrigerator, and controller 18 may control a cooling cycle and an ice-making cycle by sending one or more control signals to various electro-mechanical components. Appliance 10 may also be a clothes washing machine, and controller 18 may receive input from a user interface and manage a clothes washing cycle of operation.

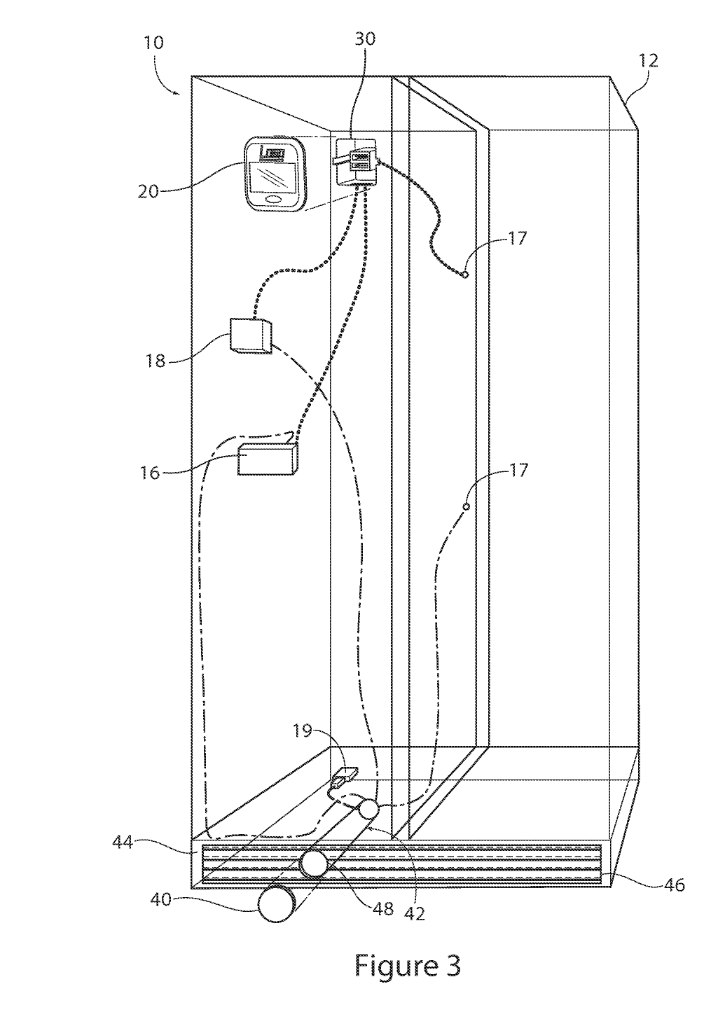

Referring to FIG. 3, controller 18 may also be connected to a service interface 30. Service interface 30 typically facilitates communication of at least one service between appliance 10 and a device, such as badge 20. The service may be supplied by service interface 30 to the device, by the device to service interface 30, or may be bi-directional between the service interface 30 and the device. For example, service interface 30 may provide one or more of the following services: electrical power communication, data communication, mechanical power communication, heat communication, substance communication, and illumination communication.

Badge 20 can be mounted to appliance 10 via the service interface 30. Service interface 30 may include various mechanical attachment mechanisms to support and secure badge 20 over service interface 30. These attachment mechanisms can be configured to permit movement of the badge 20 to selectively allow access to the service interface 30. Thus, badge 20 can be removably attached to appliance 10 via the service interface 30. There can be many embodiments of a badge attachment mechanism which selectively provides access to service interface 30. Some examples include a sliding badge, a hinged badge a snapable badge, a screwable badge, or a badge with surfaces configured to be attached via screw, bolt, vice, gripper, adhesives, velcronic material, magnetic attraction, etc.

Service interface 30 may have any of a variety of configurations depending on the type of service being transferred, including, but not limited to, a pipe, a conduit, a wire, a tube, a channel, a pathway and a fiber optic cable. For example, for electrical power or data communication, service interface 30 may include an electrically conductive wire or a wireless transmission system. Service interface 30 may facilitate illumination communication via a fiber optic cable. Further, service interface 30 may supply, or provide a bi-directional pathway for one or more of the following substances: water, air, refrigerant, coolant, steam, ice, heated water, cooled water, or pressurized fluid.

Service interface 30 may be connected to controller 18 and facilitate communication of a service, such as data communication, between controller 18 and another device. Service interface 30 may be coupled to an I/O port of controller 18 to facilitate such communication.

Service interface 30 may be connected to additional components or devices. Further, service interface 30 may facilitate the communication of multiple services between multiple devices, including communication of different types of services. For example, as shown in FIG. 3, service interface 30 may simultaneously facilitate the communication of a data service between a device, such as badge 20, and controller 18, while also facilitating the communication of a fluid service between ice/water dispenser 16, and an external water supply 17. Further, service interface 30 may also facilitate the communication of an electrical service from an external power supply 19, thereby providing electrical power.

The service interface 30 can also facilitate communication between devices external to appliance 10 and a device connected to the service interface 30 such as badge 20. Service interface 30 may include coupling points for data communication between a controller connected to the service interface 30 and a component in badge 20. The service interface 30 may include coupling points for power communication between a source of power connected to service interface 30 and a component in badge 20. Service interface 30 may include coupling points for signal transmission/reception communication between a source of signal transmission/reception connected to service interface 30 and a component in badge 20. One example of a source of signal transmission/reception is an antenna. An antenna can be provided in badge 20, integrally formed with appliance 10, or external to both appliance 10 and badge 20.

Service interface 30 is typically disposed on visible surface 14, and positioned in an easily accessible and convenient location. For example, service interface 30 may be located on a front surface of appliance 10, and positioned on an upper portion near a top surface. In the embodiment illustrated in FIG. 3, service interface 30 may be positioned behind badge 20 on a refrigerator door 13 near the top of appliance 10. In other embodiments, service interface 30 may be located on a top surface, such as on the top portion of a washing machine, or service interface 30 may be located on a control panel near a user interface. Further, service interface 30 may be located on a visible surface 14 within cavity 15.

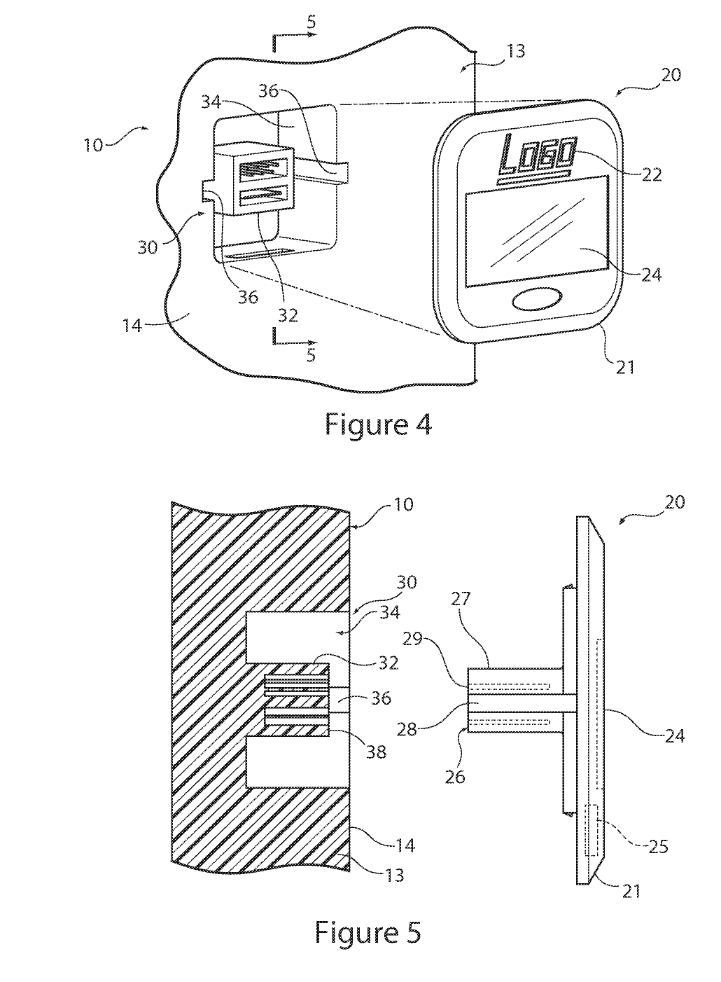

Referring to FIGS. 4 and 5, the modular system of FIG. 1 is shown, illustrating the badge 20 removably mounted to appliance 10 over service interface 30. As illustrated, badge 20 comprises a face plate 21 with indicia, such as a logo 22 and a message provider 24, provided on a front side of face plate 21. The face plate 21 can be configured to provide an aesthetically pleasing appearance to the user, such as by having a coherent or matching appearance with appliance 10, or by having a particular design scheme using various colors, textures, or surface patterns. A user can also be provided with useful information and/or advertising by the face plate 21 via the logo 22 and/or message provider 24. Badge 20 may be associated with a source of illumination (not shown) to illuminate the face plate 21, logo 22, and/or message provider 24. Some examples of a source of illumination include a light bulb, a light-emitting diode (LED), or a light pipe. The source of illumination may be electrically connected to appliance 10, such as through service interface 30, or may be electrically independent of the appliance 10. Badge 20 may include an additional component 25 that can provide an additional function to the badge 20, the appliance 10, or an accessory (not shown) for the appliance. The logo 22, message provider 24, and additional component 25 are described in more detail below.

Badge 20 may also include an attachment mechanism or system to releasably secure badge 20 to appliance 10 via the service interface 30. As illustrated, a rear protrusion 27 extends from a back side of face plate 21 and has slide rails 28 on the periphery of the rear protrusion 27. Other examples of attachment systems include multiple protrusions, rails, or magnets.

A badge service interface 26 for the badge 20 may also be provided on a back side of the face plate 21, and may include a service connector 29. The service connector 29 is illustrated as a female-type connector or receptacle. As shown in FIG. 5, service connector 29 may be disposed substantially within rear protrusion 27. Thus, the badge 20 has an integrated service interface 26 and attachment mechanism.

Badge 20 may be generally shaped and configured to engage and substantially cover service interface 30. For example, face plate 21 may be shaped and configured to substantially cover and/or enclose service interface 30, with rear protrusion 27 received within service interface 30. Further, badge 20 may further cover a portion of visible surface 14. For example, face plate 21 may extend from up to a few millimeters, to over several inches beyond service interface 30 and cover a portion of visible surface 14. Typically, badge 20 will cover a small percentage of visible surface 14, and may not cover more than ten percent (10%) of visible surface 14. Such a configuration allows a manufacturer to provide service interface 30 on a viewable portion of appliance 10, such as on visible surface 14, and maintain an aesthetically pleasing appearance by using badge 20 to cover service interface 30. Badge 20 may be further configured to engage service interface 30 and provide a barrier against the admittance of a fluid into service interface 30. For example, badge 20 may include a seal (not shown), such as a sealing ring or the like, to facilitate establishing such a barrier, or may be configured to engage service interface 30 with a tight tolerance.

While illustrated as being a one-piece assembly, the badge 20 can be provided as an assembly of modular pieces coupled together. For example, the face plate 21 can be formed as a separate piece, such that it can be detached from the attachment mechanism. This would allow for the substitution of one face plate 21 for another face plate 21, such as one with different functionality. In use, a badge with a basic or entry-level face plate 21 can be sold with an appliance 10, such as one without the message provider 24 or additional component 25, with the option of upgrading the face plate 21 for one with additional functionality, such as one with the message provided 24 and/or the additional component 25, without the need for purchasing a new attachment mechanism.

The service interface 30 includes a service connector 32 disposed in a recess 34 formed in the door 13 of the appliance 10. Service interface 30 also includes retainers 36 that are also disposed within recess 36.

Recess 34 may be a carved-out recess, as shown in FIG. 4, or recess 34 may be a moderate depression. Typically, a depression is a slight indentation that includes a smooth surface transition with a surface, such as visible surface 14. As shown in FIG. 4, an end portion 38 of service connector 32 may be positioned in close proximity to a plane defined by visible surface 14. For example, an end portion 38 of service connector 32 may be within several millimeters, or nearly flush with the plane defined by visible surface 14. As illustrated, service connector 32 extends outward from the door 13 within the recess 34, and may be configured as a male-type connector or a plug for coupling with a female-type connector or a receptacle, such as service connector 29. In another embodiment, end portion 38 of service connector 32 may be flush with or may protrude beyond visible surface 14. Recess 34 may include one or more cavity areas configured to receive at least a portion of another device. For example, badge 20 may include a rear protrusion configured to establish an interference fit with recess 34, thereby maintaining badge 20 in position over service interface 30.

Retainers 36 releasably engage with a portion of a device, including releasably engaging with a rear protrusion of badge 20. As shown, retainers 36 are horizontal indentations configured to receive a rail-like protrusion from a device. Retainers may be positioned, shaped, and configured with additional features to releasably hold a device in place, such as badge 20.

The service connector 32 is configured to complement or mate with service connector 29 of badge 20. Service connectors 29, 32 may be any type of electrical/data communication connector, and may use one or more of the following types of connections: serial, WIDE, RS-232, RS-485, universal serial bus (USB), Ethernet, power over Ethernet (POE), cable TV, UHF, fiber optic, IR, IRDA, or any signal or wave based information communication vehicle.

The retainers 36 are configured to couple with or receive the slide rails 28 on the badge 20 to hold or maintain the badge 20 in place within recess 34. The slide rails 28 and retainers 36 can create an interference fit to releasably hold badge 20 in place over service interface 30. The retainers 36 are simply one example of a grasping mechanism that can be used to releasably secure a device, such as badge 20, in place within recess 34.

Returning to FIG. 3, appliance 10 can, alternatively or additionally, comprise a second badge 40 and a service interface 42. Service interface 42 may be formed in a sub-surface 44 of appliance 10. Sub-surface 44 is typically configured to be substantially covered by a covering, such as a grill 46. As illustrated, visible surface 14 may be the outwardly facing surface or surfaces of a grill 46 that covers a bottom portion of the front of the refrigerator. Grill 46 may include an access aperture 48 that is configured to provide access to service interface 42. Furthermore, access aperture 48 may also be configured to receive and releasably secure a device in place, such as badge 40.

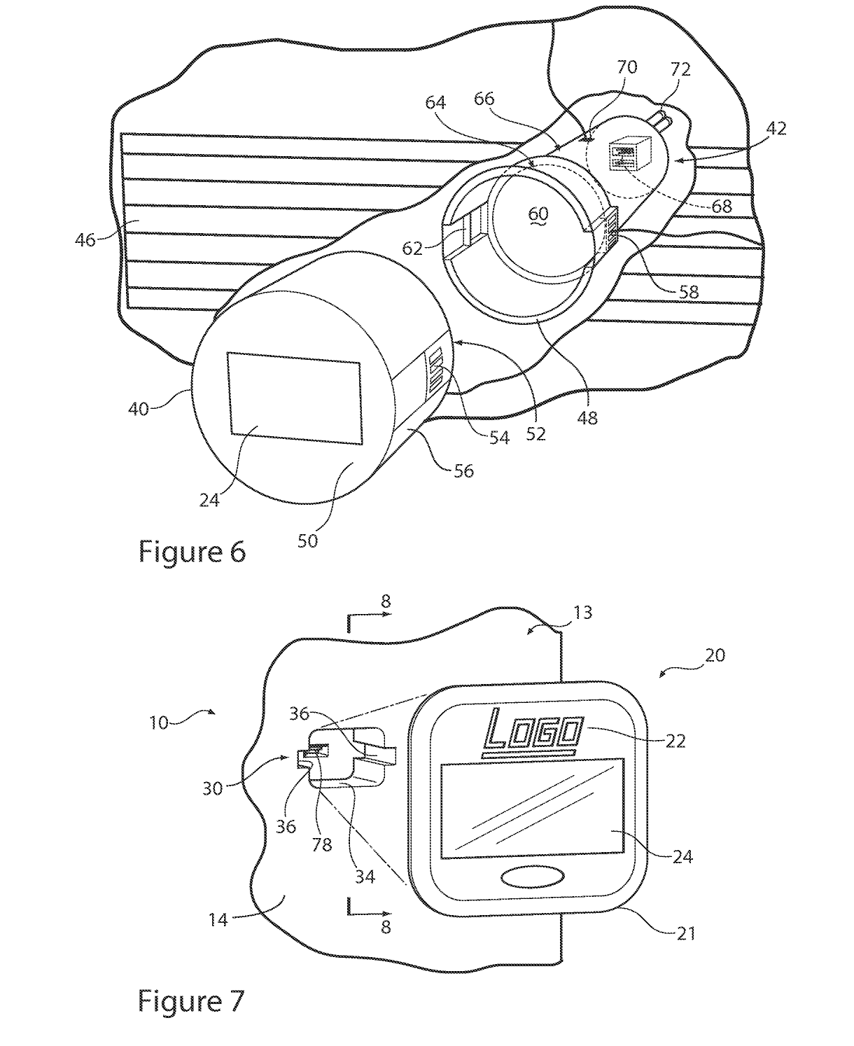

Referring now to FIG. 6, badge 40 and service interface 42 are shown disengaged in a perspective view. Badge 40 may be shaped and configured to engage and substantially cover service interface 42. For example, badge 40 may be shaped and configured to substantially cover and/or enclose service interface 42. As shown, badge 40 includes a circular face plate 50 with indicia, such as a message provider 24, provided on a front side of face plate 50. A user can also be provided with useful information and/or advertising by the face plate 50 via the message provider 24. Badge 40 also includes a badge service interface 52. As illustrated, the badge service interface 52 comprises at least one service connector 54 provided in a side wall 56 of the badge 40. The service interface 52 is illustrated as being a substantially flat or planar conductive surface.

Service interface 42 includes one or more service connectors 58, 68, 70 disposed in a recess 60 formed in the sub-surface 44 of the appliance 10 and generally aligned with the access aperture 48 in the grill 46. Further, service interface 42 may include an attachment mechanism 62 that is configured to mate with a corresponding attachment mechanism (not shown) on badge 40. For example, badge 40 may include a protrusion configured to establish an interference fit with attachment mechanism 62, thereby maintaining badge 20 in position within service interface 30.

Service interface 42 may also be configured to detachably secure one or more devices. For example, service interface 42 may receive an accessory (not shown) in addition to badge 40. The recess 60 may include a first portion 64 that is configured to receive a first device and a second portion 66 that is configured to receive a second device. First and second portions 64, 66 may be configured according to the device they are intended to receive, such as being shaped and sized appropriately depending on the shape and size of the intended device. For example, first portion 64 may be configured to receive the badge 40 and second portion 66 may be configured to receive an accessory, such as a water filter cartridge (not shown).

The service connectors 58, 68, 70 are configured to complement or mate with other service connectors. As illustrated, service connector 58 mates with service connector 54 on badge 40. Service connectors 68 and 70 may mate with service connectors provided on different accessories (not shown). Service connectors 58, 68, 70 may be coupled with service lines or pathways for the transfer of a service to or from the service interface 40. As illustrated service lines 72 for the service connector 70 are visible, as may, for example, be conduits for carrying a substance, such as water.

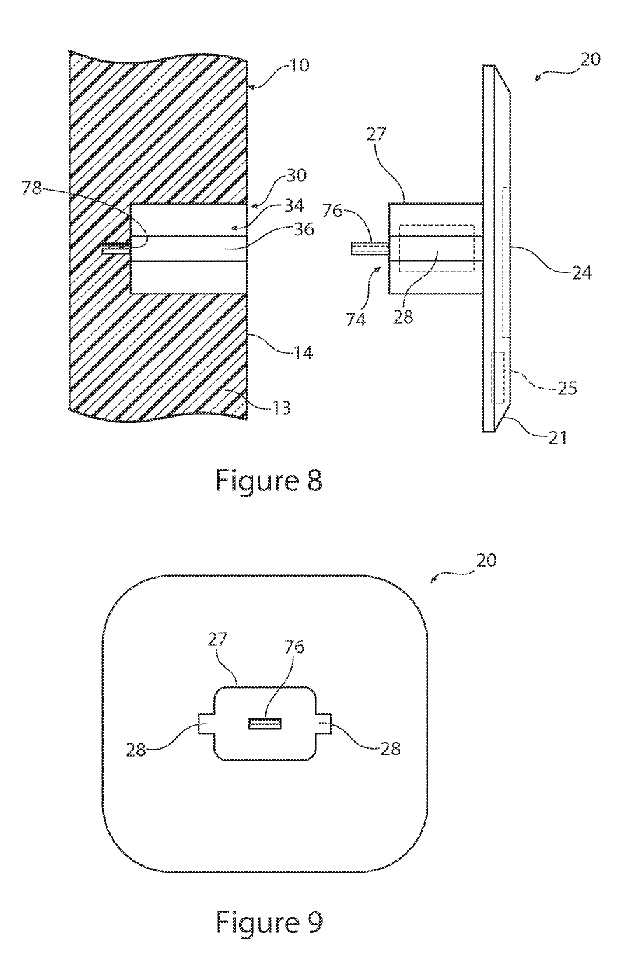

Referring to FIGS. 7-9, a second embodiment of modular system comprising an appliance 10, a badge 20 and a service interface 30 is shown. The second embodiments of the badge 20 and service interface 30 are similar in some respects to those of the first embodiment, and like elements will be identified using the same reference numerals where possible. For the second embodiment, badge 20 comprises a badge service interface 74 with a service connector 76 shown as a male-type connector or plug. The service connector 76 extends from the rear protrusion 27. Thus, the badge 20 has an integrated service interface and attachment mechanism. The service interface 30 includes a service connector 78 disposed in recess 34. The service connector 78 is illustrated as a female-type connector or receptacle, and can selectively receive the service connector 76 of the badge. As shown in FIG. 7, service connector 78 may be positioned deep within recess 34, thereby, providing additional space in recess 34 for receiving a second device, such as an accessory. In one example, the service connectors 76, 78 can be a USB-type plug and socket, respectively.

FIG. 9 is a rear view of badge 20, showing rear protrusion 27 having two slide rails 28, and service connector 76 disposed on rear protrusion 27. Slide rails 28 are typically configured to mate with or complement retainers 36, thereby creating an interference fit and releasably securing badge 20 to service interface 30.

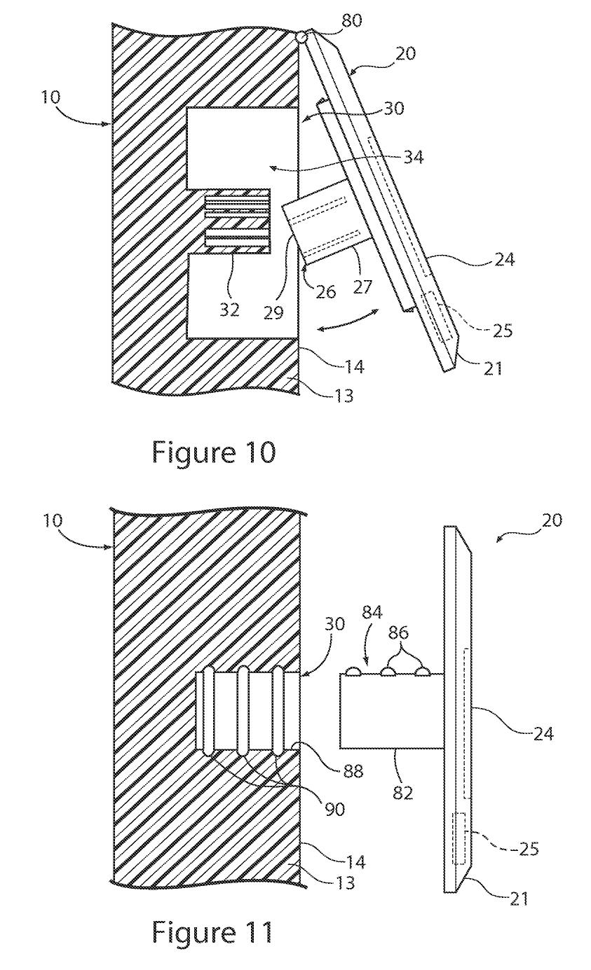

Various means to support and secure badge 20 to appliance 10 adjacent service interface 30 may be used. FIGS. 10-13 show other embodiments of attachment systems for the badge 20. These embodiments of the badge 20 and service interface 30 are similar in some respects to those of the first embodiment, and like elements will be identified using the same reference numerals where possible. While the attachment systems are illustrated as coupling a badge 20 with the appliance 10 and/or service interface 30, it is understood that the attachment systems can be configured to accommodate an accessory in combination with the badge 20, or be used to couple an accessory to the appliance 10 and/or service interface 30 without the badge 20.

Referring to FIG. 10, a modular system according to a third embodiment of the invention is shown, and comprises appliance 10, badge 20, and service interface 30. In the third embodiment, badge 20 is pivotally coupled to the appliance 10 for movement between a closed position, not shown, in which the badge 20 closes the opening of the recess 34, and an open position, shown, in which the badge 20 exposes the opening of the recess 34. As illustrated, the face plate 21 is affixed to the appliance 10 by at least one hinge 80 that movably connects badge 20 to appliance 10. The hinge 80 can be adjacent the recess 34 so that the badge 20 can be pivotally coupled to appliance 10 proximate to the service interface 30. Optionally, the attachment mechanism can be configured so that in the closed position the service connector 29 of the badge 20 is brought into contact or otherwise coupled with the service connector 32 of the service interface 30.

Referring to FIG. 11, a modular system according to a fourth embodiment of the invention is shown, and comprises appliance 10, badge 20, and service interface 30. In the fourth embodiment, badge 20 is removably mounted to appliance 10 over service interface 30 so that the badge 20 can be easily physically separated from the appliance 10 by a user without the use of tools. Badge 20 includes a badge service interface 84 having a rear protrusion 82 that extends from a back side of face plate 21 and multiple spring-loaded insertion pins 86 located on the rear protrusion 82. Service interface 30 includes a recess 88 formed in the door 13 of the appliance 10 and multiple grooves 90 that receive the pins 86 when the badge 20 is coupled to the service interface 30. The pins 86 releasably mate with the grooves 90 to retain the rear protrusion 82 in the recess 88, thereby attaching the badge 20 to the appliance 10 via the service interface 30. The pins 86 and grooves 90 can further act as service connectors for the badge 20 and service interface 30 respectively, such as by having electrically conductive surfaces that mate to transmit an electromagnetic service such as electrical power or data therebetween.

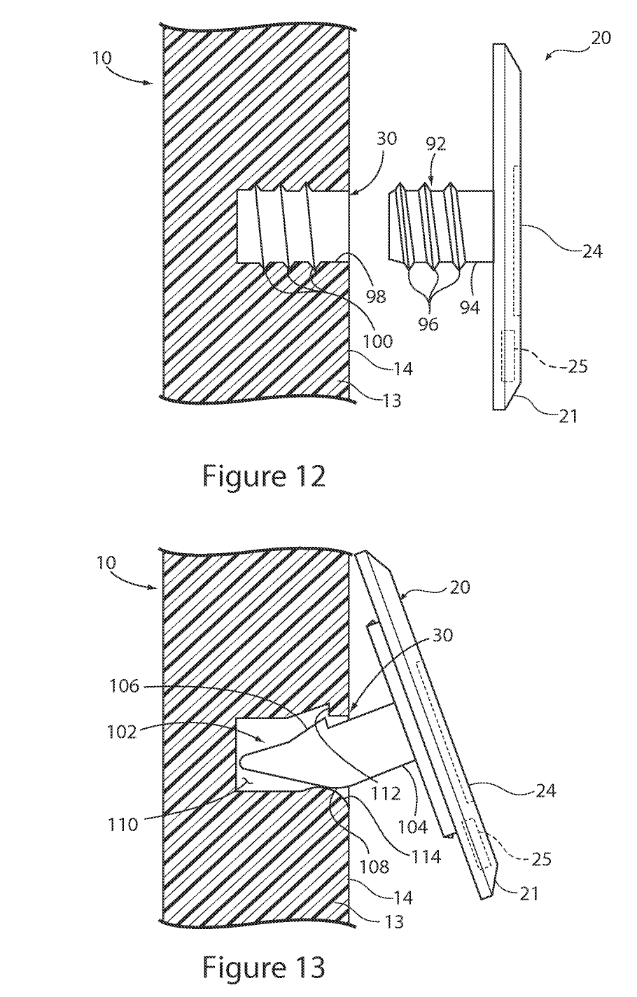

Referring to FIG. 12, a modular system according to a fifth embodiment of the invention is shown, and comprises appliance 10, badge 20, and service interface 30. In the fifth embodiment, badge 20 is removably mounted to appliance 10 over service interface 30 so that the badge 20 can be easily physically separated from the appliance 10 by a user without the use of tools. Badge 20 includes a badge service interface 92 having a rear protrusion 94 that extends from a back side of face plate 21 and external screw threads 96 formed on the rear protrusion 94. Service interface 30 includes a recess 98 formed in the door 13 of the appliance 10 and internal screw threads 100 that mate with external screw threads 96 when the badge 20 is coupled to the service interface 30. The screw threads 96, 100 releasably mate to retain the rear protrusion 94 in the recess 98, thereby attaching the badge 20 to the appliance 10 via the service interface 30. The screw threads 96, 100 can further act as service connectors for the badge 20 and service interface 30 respectively, such as by having electrically conductive surfaces that mate to transmit an electromagnetic service such as electrical power or data therebetween.

Referring to FIG. 13, a modular system according to a sixth embodiment of the invention is shown, and comprises appliance 10, badge 20, and service interface 30. In the sixth embodiment, badge 20 is removably mounted to appliance 10 over service interface 30 by a mechanical connection so that the badge 20 can be easily physically separated from the appliance 10 by a user without the use of tools. Badge 20 includes a badge service interface 102 having a rear protrusion 104 that extends from a back side of face plate 21, with a projection 106 and a transition surface 108 formed on the rear protrusion 104. Service interface 30 includes a recess 110 formed in the door 13 of the appliance 10 and having a catch 112 and a transition surface 114 formed in the recess 110. The transition surface 108 of the badge 20 first engages the transition surface 114 of the recess 110. As transition surface 108 slides along transition surface 114, projection 106 is brought into engagement with the catch 112 as the rear protrusion 104 comes into alignment with the recess 110, thereby attaching the badge 20 to the appliance 10 via the service interface 30. The projection 106 and catch 112 can further act as service connectors for the badge 20 and service interface 30 respectively, such as by having electrically conductive surfaces that mate to transmit an electromagnetic service such as electrical power or data therebetween.

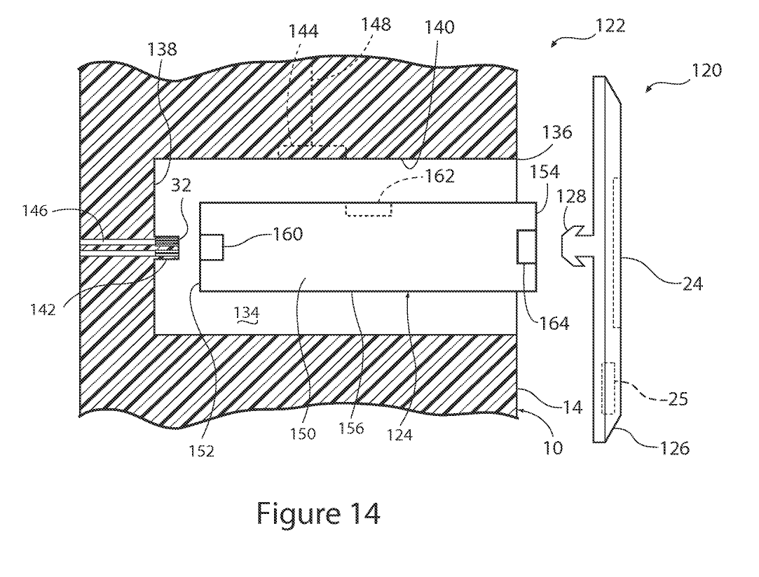

Referring to FIGS. 14-16, a modular system according to a seventh embodiment of the invention is shown, and comprises appliance 10, a badge 120, a service interface 122, and an accessory 124. In this embodiment, the appliance 10 is similar to that of the first embodiment, and like elements will be identified using the same reference numerals where possible. In the seventh embodiment, accessory 124 is coupled to appliance 10 via the service interface 122, and badge 120 is removably coupled to accessory 124 over the service interface 122. However, badge 120 can alternately be configured to mechanically couple to appliance 10 and/or service interface 122.

Badge 120 comprises a face plate 126 with indicia, such as a message provider 24, provided on a front side of face plate 126. Badge 120 may include an additional component 25 that can provide an additional function to the badge 120, the appliance 10, or the accessory 124. Badge 120 may also include an attachment system to releasably secure badge 120 to accessory 124. As illustrated, a pair of hooks 128 extend from a back side of face plate 126. A badge service interface 130 for the badge 120 may also be provided on a back side of the face plate 126, and may include a service connector 132.

Service interface 122 comprises a recess 134 extending from an opening 136 in the visible surface 14 of the appliance 10. As illustrated, the recess 136 has an elongated shape to selectively admit and substantially enclose the accessory 124, and includes a base wall 138 and a side wall 140 extending between the base wall 138 and the opening 136. A first service connector 142 is disposed on the base wall 138 and a second service connector 144 is disposed on the side wall 140, each for selectively providing a service to the accessory 124. The first service connector 142 is illustrated as a male-type connector or plug and is coupled with service lines 146 for the transfer of a service to or from the first service connector 142. The second service connector 144 is coupled with a service line 148 for the transfer of a service to or from the second service connector 144.

The first and second service connectors 142, 144 can provide the same service or a difference service. For example, first service interface 142 can communicate a substance service and service lines 146 can be conduits for carrying a substance, such as water, while second service interface 144 can communicate an electromagnetic service and service lines 146 can be wiring for transmitting electrical power or data.

Accessory 124 comprises a housing or body 150 configured for insertion into the recess 134. As illustrated, the body 150 has an elongated shape and includes a rear end wall 152, a front end wall 154, and a side wall 156 extending between the end walls 152, 154. The body 150 may be sized and shaped to establish an interference fit with recess 134, thereby maintaining accessory 124 in position within the service interface 122. A pair of retainers 158 are formed in the front end wall 154 and selectively receive the hooks 128 on the badge 120 to couple the badge 120 to the accessory 124.

Accessory 124 further comprises one or more service interfaces, each having an associated service connector 160-164 that is configured to couple with a service connector of the badge 120 or the service interface 122. As illustrated, a first service connector 160 is disposed on the rear end wall 152, a second service connector 162 is disposed on the side wall 156, and a third service connector 164 is disposed on the front end wall 154. The first service connector 160 is illustrated as a female-type connector or plug, and is configured to couple with the first service connector 142 of the service interface 122, thereby, communicating a service with appliance 10 via service interface 122. The second service connector 162 is configured to couple with the second service connector 144 of the service interface 122, thereby communicating another service with appliance 10 via service interface 122. The third service connector is configured to couple with the service connector 132 of the badge 120, thereby communicating a service with the badge 120.

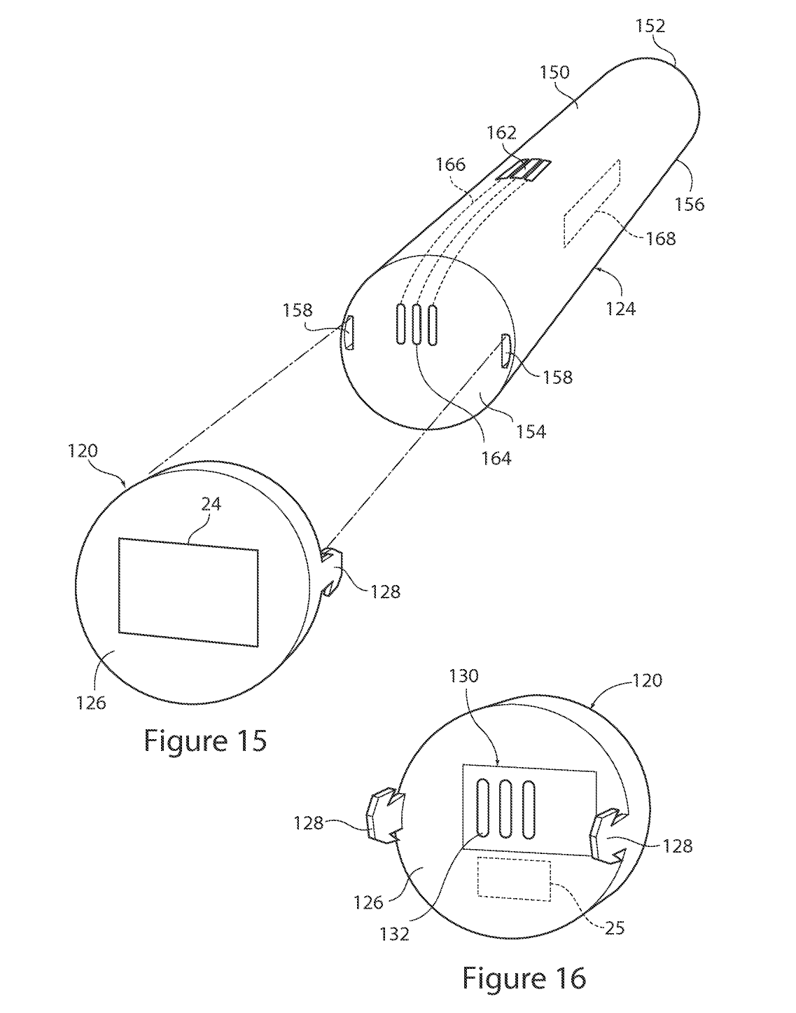

The service connectors 160-164 can provide the same service or a difference service. Furthermore, the service connectors 160-164 can function independently of each other, or can be interconnected. For example, the second and third service connectors 162, 164 are shown as being interconnected by service lines 166 in FIG. 15. Accessory 124 thereby, is capable of facilitating the communication of a service between appliance 10 and badge 120.

Accessory 124 may also include a functional component 168 that can provide an additional function to the accessory 124 itself, or to the appliance 10 or badge 120. The functional component 168 can be operably coupled to any of the service connectors 160-164 to utilize a service provided by the appliance 10 or badge 120, or to supply a service to the appliance 10 or badge 120. The functional component 168 is described in more detail below.

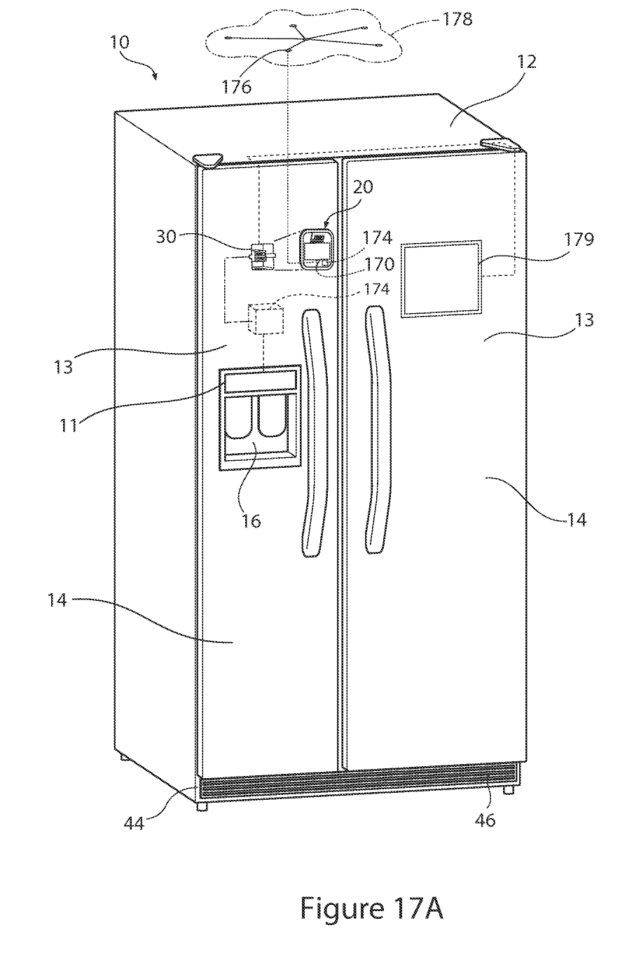

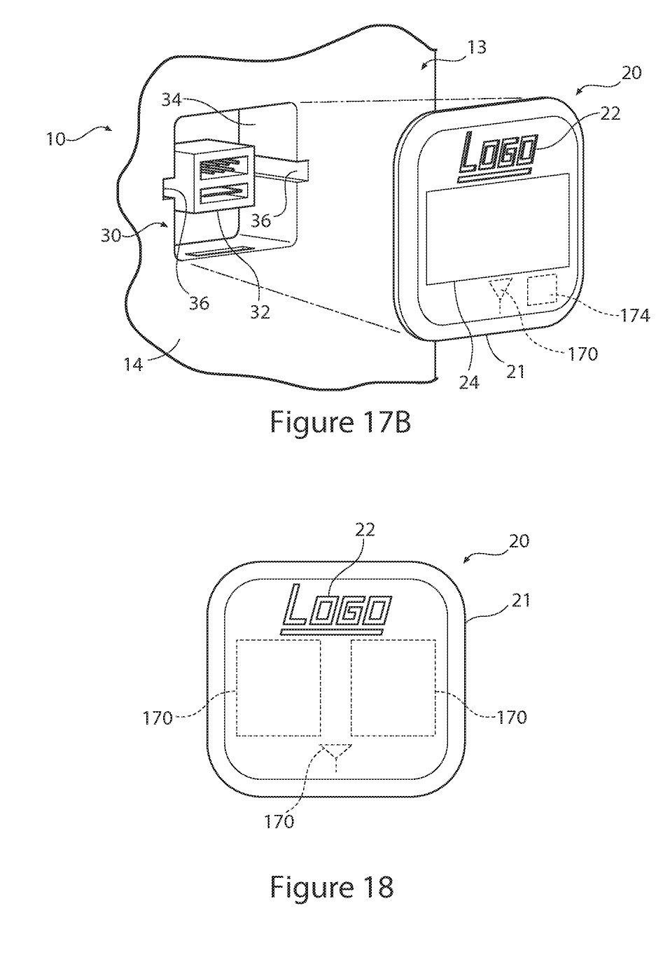

Referring to FIG. 17A-18, an eighth embodiment of a modular system according to the invention is shown, and comprises an appliance 10, a badge 20 and a service interface 30. The eighth embodiment of the modular system is similar in some respects to the modular system of the first embodiment, and like elements will be identified using the same reference numerals where possible. For the eighth embodiment, the badge 20 comprises at least one antenna 170. As illustrated, the antenna 170 is disposed in the face plate 21 of the badge 20. As such, antenna 170 is hidden from view, but is able to be located on visible surface 14 of the appliance 10. Further, antenna 170 is also capable of being communicatively coupled to a component of the appliance 10 through service interface 30. It will be appreciated that badge 20 may include more than one antenna 170. For example, as further illustrated by FIG. 18, badge 20 may include three antennas 170 that are disposed within the face plate 21. The antenna 170 can be at least one of a patch antenna, a slot antenna, a microstrip antenna, a printed antenna, a monopole antenna, a dipole antenna, and a wire antenna. Badge 20 and antenna 170 may be separate devices, or antenna 170 may be integrated within badge 20 as illustrated in FIGS. 17A-18.

The modular system further includes a controller 174 that is operably connected to the antenna 170 and that is configured to selectively provide operational instructions to the appliance 10 and/or the badge 20. As illustrated, the controller 174 can be provided in the appliance or the badge 20. Alternatively, components of the controller 174, including multiple controllers, can be provided in both of the appliance 10 and badge 20, and can collectively make up the controller 174 that is operably connected to the antenna 170. When provided with the appliance 10, the controller 174 can be configured to control the physical operation performed by the appliance 10. In such an arrangement, the service interface 30 can be used to provide a communication link between the antenna 170 and the controller 174.

The modular system can further include a communication node 176 for connecting the antenna 170 to a communication network or system 178, with the antenna 170 providing wireless communication between the controller 174 and the communication node 176. As illustrated, the communication node 176 can be separate from the appliance 10. Alternatively, the communication node 176 can be part of or integrated with the appliance 10. Examples of the communication network or system 178 include an appliance network, a computer network, a peer-to-peer communication system, a cellular telephone system, and a voice-over-IP (VoIP) system.

The modular system can be provided with means for limiting the range of radio signals communicated to or from the antenna 170. For example, the range of the antenna 170 can be limited to within the home. In one arrangement, a portion of the appliance 10 or badge 20 may be made from a material having the material property of attenuating a radio frequency signal. For example, a portion of the badge 20, the visible surface 14 near the service interface 30 or a portion of the service interface 30 itself may be made of iron, nickel, chromium, or tungsten, or alloys, composites, or combinations thereof.

The modular system can further include a radio communication device (“RCD”) coupled to the antenna 170 for communicating with radio waves received by the antenna. The RCD can optionally be disposed within the appliance 10 or the badge 20. If the appliance 10 includes an RCD and the badge 20 does not, the badge service interface can include a coupling point for a radio frequency (“RF”) signal to connect the RCD to the integrated antenna 170. If the badge 20 includes the RCD, the badge service interface can include a coupling point for power and/or data communications. In yet another contemplated arrangement, the badge 20 may contain a battery in addition to the RCD. In this case, the badge service interface may include a coupling point for data communications. Also in this case, the badge 20 may be configured to enable a user to replace the battery.

In yet another contemplated arrangement, the badge 20 may include a radio communication device and not an antenna. In this case, the badge service interface may include a coupling point for an RF signal such to connect the radio communication device to an antenna external from the badge 20. Also in this case, the badge 20 may include either a battery or a coupling point for power communications to power the communication device.

As illustrated, the RCD comprises a television display 179 provided on one of the doors 13 of the appliance 10 and coupled to the service interface 30. As illustrated, the coupling between the television display 179 and the service interface 30 can be a wired connection running through the hinges of the doors 13, although a wireless connection between the antenna and television display 179 is also possible. The antenna 170 can receive a wirelessly broadcast signal, and communicate the signal to the television display 179 via the coupling of the badge 20 with first service interface 30. Other RCDs, non-limiting examples of which include a radio, a transceiver, a computer, an information display device, a telecommunications device, a memory storage device, and an energy-measuring device, can similarly be provided with the appliance, and coupled with the service interface 30.

The RCD can include circuitry for communicating radio frequency signals received by the antenna 170. For example, if the RCD is provided in the badge 20, the circuitry can be couple to the badge service interface to communicate radio frequency signals to the badge service interface. The circuitry can, for example include a resistor or an impedance matching circuit, which may include passive and active devices such as resistors, capacitors, inductors, diodes, transistors, or integrated circuits. The circuitry could further include noise suppression filters and amplifier circuits.

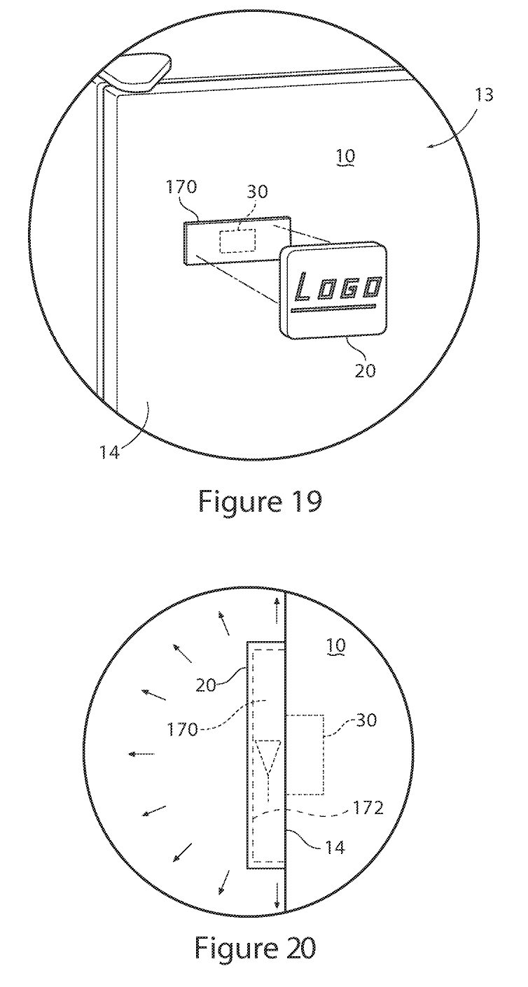

Referring to FIGS. 19-20, an ninth embodiment of a modular system according to the invention is shown, and comprises an appliance 10, a badge 20 and a service interface 30. The ninth embodiment of the modular system is similar in some respects to the modular system of the eighth embodiment, and like elements will be identified using the same reference numerals where possible. For the ninth embodiment, badge 20 and antenna 170 are separate devices, and antenna 170 is shown engaging service interface 30, and badge 20 is shown disengaged from antenna 170 and service interface 30. Service interface 30 may include one or more retainers for releasably engaging with badge 20 and/or antenna 170. Antenna 170 can be configured to releasably engage service interface 30, such as by coupling with features of the service interface such as service connector 32, recess 34, and retainers 36 shown in FIG. 4.

In addition, badge 20 is configured to releasably engage antenna 170 and/or service interface 30. For example, antenna 170 may be configured to releasably engage service interface 30, and badge 20 may be configured to releasably engage antenna 170. Alternately, badge 20 and antenna 170 may both be configured to releasably engage service interface 30, or may be configured to releasably engage another engagement feature on visible surface 14, such as by using a releasable fastener. Badge 20 and antenna 170 may use one or more retainers that are positioned, shaped, and configured to releasably hold antenna 170 and badge 20 in place over service interface 30.

As shown in FIG. 20, badge 20 may also be configured to substantially cover antenna 170 to ensure a finished or aesthetically pleasing appearance on visible surface 14. Badge 20 may include a hollowed-out rear portion 172 that can envelop and cover antenna 170, thereby providing an aesthetically pleasing appearance while also allowing antenna 170 to be positioned beyond a plane defined by visible surface 14. As shown in FIG. 20, antenna 170 is positioned on visible surface 14, such that at least a portion of antenna 170 protrudes beyond a plane defined by visible surface 14. With a substantial portion or all of antenna 170 positioned beyond visible surface 14, a wireless signal propagation pattern of at least approximately 180° as indicated by the arrows in FIG. 20 is possible.

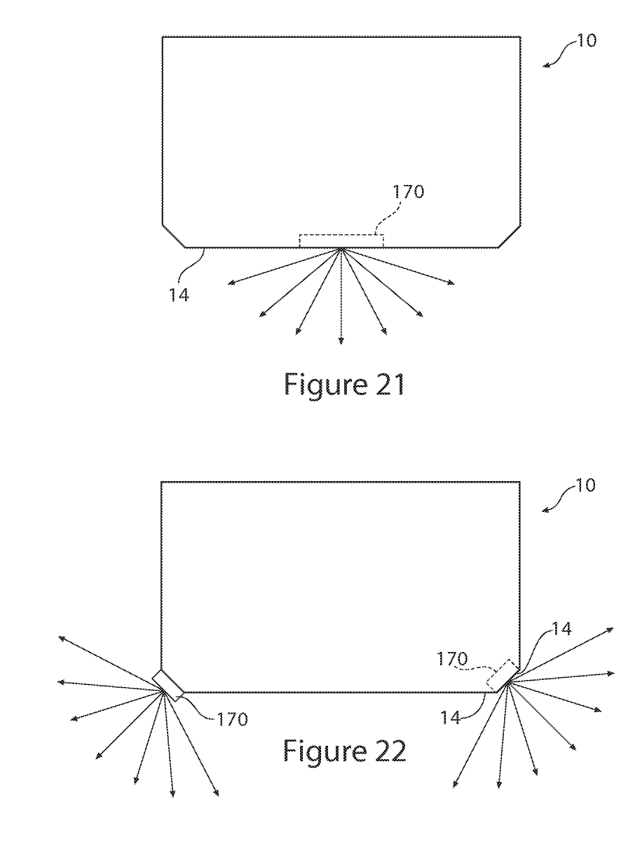

FIG. 21 is a top view of a modular system according to a tenth embodiment of the invention comprising an appliance 10 and an antenna 170. The tenth embodiment of the modular system is similar in some respects to the modular system of the eighth and ninth embodiments, and like elements will be identified using the same reference numerals where possible. For the tenth embodiment, antenna 170 is positioned within and flush with visible surface 14 of appliance 10. For example, antenna 170 may be positioned within recess 34 of service interface 30 (see FIG. 4). The arrows illustrate one example of a signal propagation pattern emanating from antenna 170. The precise signal propagation pattern may depend on multiple factors, such as the type of antenna 170 used, the placement within or beyond visible surface 14, the frequency of the wireless signal, etc. Certain considerations may be a factor when designing appliance 10, and may influence the placement, position, and orientation of antenna 170, service interface 30, badge 20, or the like.

FIG. 22 is a top view of a modular system according to an eleventh embodiment of the invention comprising an appliance 10 and multiple antennas 170. The eleventh embodiment of the modular system is similar in some respects to the modular system of the eighth, ninth, and tenth embodiments, and like elements will be identified using the same reference numerals where possible. For the eleventh embodiment, one antenna 170 is positioned within and flush with visible surface 14. In this case, for example, the antenna 170 may be integrated with the appliance 10, or may be part of an accessory attached to a service interface of the appliance. Another antennas 170 is positioned such that at least a portion of the antenna 170 is beyond a plane defined by visible surface 14, thereby protruding beyond visible surface 14. In this case, for example, the antenna 170 may be integrated with a badge that is attached to a service interface of the appliance, in a similar manner as the eighth embodiment shown in FIGS. 17A-18. Of course, both antennas 170 could be flush with visible surface 14, or both antennas 170 could protrude beyond the visible surface 14. As shown in FIG. 22, appliance 10 may include visible surfaces 14 on angled corners, and both antennas 170 may be disposed on the angled corners. The arrows illustrate one example of a signal propagation pattern emanating from antennas 170. Such positioning, and use of multiple antennas 170, may enable appliance 10 to wirelessly communicate with devices that are positioned on either side of appliance 10. For example, controller 18 of FIG. 1 may include a transceiver that is connected to each antenna 170 through a service interface 30.

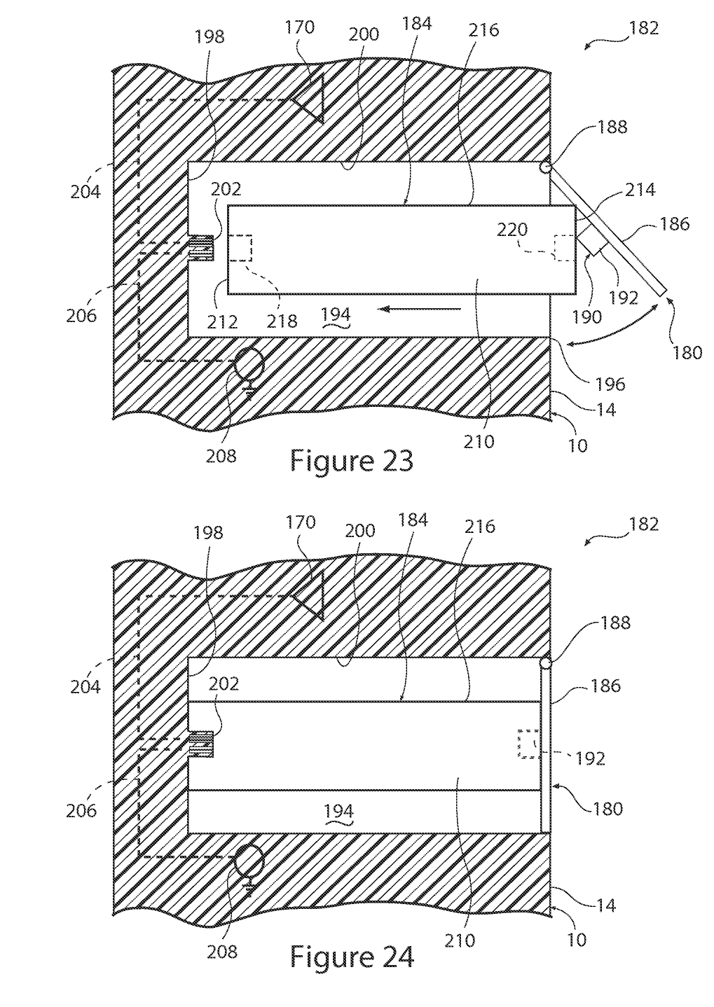

Referring to FIGS. 23 and 24, a modular system according to a twelfth embodiment of the invention is shown, and comprises appliance 10, cover 180, service interface 182, and an accessory 184. In this embodiment, the appliance 10 is similar to that of the first embodiment, and like elements will be identified using the same reference numerals where possible. In the twelfth embodiment, accessory 184 is coupled to appliance 10 via the service interface 182, and cover 180 is pivotally coupled to appliance 10 for movement between a closed position, shown in FIG. 24, and an open position, shown in FIG. 23.

Cover 180 comprises a face plate 186 and a hinge 188 that movably connects cover 180 to appliance 10. A service interface 190 for the cover 180 may also be provided on a back side of the face plate 186, and may include a service connector 192 for coupling with accessory 184. Alternately, a dummy connector can be provided in place of the service interface 190 that permits only a mechanical coupling with accessory 184 and does not permit the transfer of a service. While not shown, indicia can be provided on a front side of face plate 186, such as by a logo or message provider. In this case, cover 180 would be considered a badge.

Service interface 182 comprises a recess 194 extending from an opening 196 in the visible surface 14 of the appliance 10. As illustrated, the recess 194 has an elongated shape to selectively admit and substantially enclose the accessory 184, and includes a base wall 198 and a side wall 200 extending between the base wall 198 and the opening 196. A service connector 202 is disposed on the base wall 198 for selectively providing a service to the accessory 184. The service connector 202 is illustrated as a male-type connector or plug and is coupled with service lines 204, 206 for the transfer of a service to or from the service connector 202. As illustrated service line 204 can couple an antenna 170 to the service connector 202, and service line 206 can couple a power supply 208 to the service connector 202. Therefore, the service connector 202 can receive data from the antenna 170 via the service line 204 and power from the power supply 208 via the service line 206.

Accessory 184 comprises a housing or body 210 configured for insertion into the recess 194. As illustrated, the body 210 has an elongated shape and includes a rear end wall 212, a front end wall 214, and a side wall 216 extending between the end walls 212, 214. The body 210 may be sized and shaped to establish an interference fit with recess 194, thereby, maintaining accessory 184 in position within the service interface 182.

Accessory 184 further comprises one or more service interfaces, each having an associated service connector 218, 220 that is configured to couple with a service connector of the cover 180 or the service interface 182. As illustrated, a first service connector 218 is disposed on the rear end wall 212 and a second service connector 220 is disposed on the front end wall 214. Both service connectors 218, 220 are illustrated as a female-type connector or plug, and are configured to respectively couple with the service connector 202 of the service interface 180, thereby communicating a service with appliance 10 via service interface 182, and with the service connector 192 of the cover 180, thereby communicating a service with the cover 180. Some non-limiting examples of accessory 184 include a water filter, a water purifier, an air purifier, a motion detector, a transceiver, a wireless transceiver, a microcontroller, a processor, a microprocessor, a dispenser, a network interface adapter, and a memory.

In the open position shown in FIG. 23, the cover 180 exposes the opening 196 and permits removal or insertion of accessory 184 into service interface 182. In this position, the first service interface 218 of the accessory 184 can couple with the service connector 202 of the service interface 182. In the closed position shown in FIG. 24, the cover 180 couples with the second service connector 220 of the accessory 184 and closes the opening 196 of the service interface 182. Alternately, the closing of the cover 180 can effect coupling of the accessory 184 to the service interface 182 as well.

It is understood that any of the appliance service interfaces disclosed herein may be configured to receive an accessory that provides an additional function to the appliance, and that any of the modular systems can further include one or more accessories.

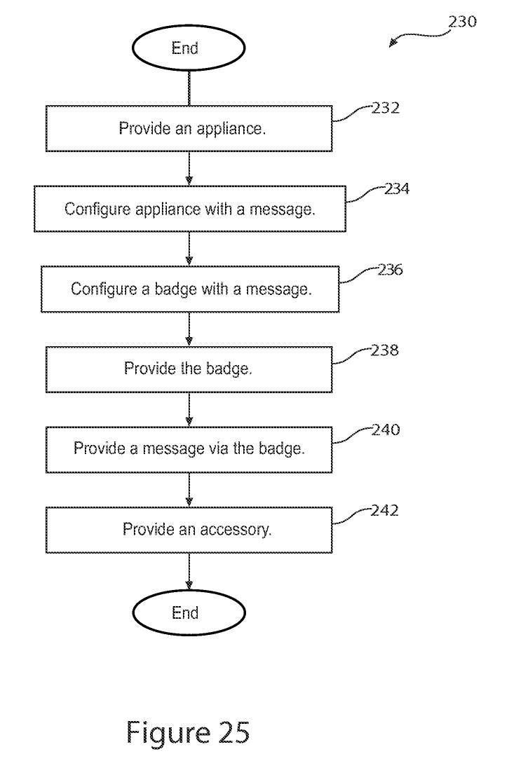

FIG. 25 is a flow diagram according to a thirteenth embodiment of the invention showing a process 230 for promoting the purchase of an accessory. As previously discussed, an accessory is generally any device configured to removably couple with a service interface. As shown in FIG. 25, process 230 begins in step 232 by providing an appliance. Typically, a manufacturer or supplier will provide an appliance that includes a service interface to a retail outlet, a wholesaler, a distributor, or to a user/consumer.

Next, in step 234, the appliance is configured with a message. To promote the purchase of an accessory, the appliance is configured with an advertisement message. The advertisement message may simply provide information about different accessories, or may provide information about the functions that such accessories may provide. For example, an advertisement message may include a description of an accessory, a website address (URL) regarding information about one or more accessories, or information regarding a sale or discount on an accessory, a targeted advertisement based on a history of use of appliance, or even a question to tout the virtues of one or more accessories, such as “Wouldn't it be nice if your oven called you when the timer goes off?” Configuring the appliance may include programming one or more messages in a controller of the appliance, or including software on the controller for dynamically generating and providing a message. Configuring the appliance may also include programming or configuring the controller to provide information or data to a badge through a service interface. Additionally, the advertisement message can be from a supplier or marketer of goods such as advertisements for other common household goods such as food stuffs, cleaners and cleaning agents, detergents, softeners, cosmetics, soaps, shampoos, and the like. Also, the advertisement message can be about a subscription service such as recipe clubs, buying clubs, music clubs, news services, and financial services which would entitle the subscriber to certain notifications, access to information, and other offers. Also, the message can be from a source of information about a resource. An example of a source is a utility company or government agency and an example of a resource is water, gas, electricity, air and the like. An example of messages from a source of information about a resource can be a monthly bill statement, resource usage statistics, current resource pricing information, offers of resource curtailments, notifications of impending resource shortages, and notifications of service disruptions including boil orders, clean air advisories, and the like.

Next, in step 236, a badge is configured with a message. Again, to promote the purchase of an accessory, the badge is configured with an advertisement message, as described above. The badge may include hardware and software for selectively providing a message using a message provider. Furthermore, the badge may include hardware and software to communicate with a controller of the appliance, and selectively provide a message based in part on information received from the controller, for example through service connectors. For example, the badge may select a message based in part on a cycle of operation.

Next, in step 238, the configured badge is provided. Generally, a manufacturer, reseller, retail outlet, etc. provides the badge to a user. The badge may be provided to a user at the same time appliance is provided, or the badge may be provided at another time.

Next, in step 340, the badge provides a message to a user through a message provider. The message may be provided on a fixed time schedule, on a periodic time schedule, or may be provided in response to a sensor input, data from the appliance controller, or some other event. The provided message may be an advertisement message to promote the purchase or acquisition of an accessory.

Next, in step 242, an accessory is provided. Again, an accessory may be provided by a manufacturer, reseller, retailer, or some other entity. The accessory is typically provided to a user of the appliance for use with the appliance.

Logo on Badge

The logo 22 on a badge provides information to a user that can distinguish the appliance on which is it provided from other appliances. For example, logo 22 may be a model, brand, retailer, or manufacturer of the appliance, or a model, brand, retailer, or manufacturer of an accessory for the appliance. A logo 22 can be an ornamental trigger configured to invoke an emotional response associated with the appliance fit, form, finish, or performance from a user when a user sees the badge. A single appliance or accessory can have more than one logo, and more than one logo 22 can be shown on a badge.

In one contemplated embodiment, a badge may use a source of illumination to enhance the information provided by the logo 22. For example, the badge may include a light source and a panel that includes a logo 22 thereon that is only visible when light is applied from the light source. A badge may be configured to selectively illuminate the panel, thereby, illuminating the logo 22, when the badge is connected to the appliance or a service interface of the appliance.

The logo 22 may be integrated with the message provider 24 such that the logo 22 is a message or part of a message provided by the message provider 24. For example, message provider may simultaneously communicate a logo 22 and at least one message.

Message Provider on Badge

Message provider 24 provides a message to a user, such as through a sight, sound, smell or touch. As such, message provider 24 may be a visual display, an audio device, an olfactory system, a tactile system, or any combination thereof, capable of being installed in a badge. A visual display provides a message visually; examples include a liquid crystal display (LCD), a light-emitting diode (LED) display, a backlit display, a vacuum fluorescent display (VFD), or a laser that is used to create a visual message. An audio device provides a message acoustically; examples include a speaker, such as a piezoelectric speaker. An olfactory system provides a message through a scent or odor. A tactile system provides a message that is perceptible by touch; examples include a refreshable Braille display, or any other electro-mechanical device for displaying Braille characters or other tactile information.

Message provider 24 may combine any of these types of messages, such as combining a visual message with a tactile message which may convey the same information as the visual message. In addition, message provider 24 may include components or features which enhance a message provided by the message provider 24. For example, a message may be enhanced by illuminating the message, brightening the message, changing a color of the message, backlighting the message, flashing the message, supplementing the message, increasing the volume of the message, and adding a sound to the message.

Message provider 24 can provide one or more different categories of messages to a user. Some examples of such categories are, but are not limited to, an advertisement message, an appliance message, a personal message, and a status message.

An advertisement message may attempt to entice a user to purchase or acquire an accessory. An accessory is generally any device configured to removably couple with a service interface, and may communicate a service with a service interface. An advertisement may also be for additional products or services relating to the appliance. Additional products can be items like dishwasher detergent, oven mitts, or cookware. Services can include, but are not limited to, appliance repair, food delivery, cooking classes, data services, and content services. For example, data services can include periodic remote appliance check-ups, and automatic software upgrades. Content services can include recipe services, photo services, music services, and calendaring services.

An appliance message is generally a message regarding an appliance to which a badge is coupled. For example, an appliance message may be an error message or a maintenance message. A badge may receive data from a controller of the appliance, interpret the data, and provide an appliance message via the message provider 24 based on the received data. A service connector of the badge may be coupled to the message provider 24 to receive data, information, or status messages from the appliance controller.

A personal message is typically a message that is provided by a user to the badge, the appliance, or an accessory of the appliance. Examples of personal messages include a greeting, a reminder, or some other personalized message. A user may provide a personal message to the badge, appliance, or accessory though various mechanisms. In one mechanism, a personal message can be provided to a controller of the appliance, which may then provide the message to the badge for communication through the message provider 24.

A status message indicates a status of the appliance, an accessory for the appliance, or the badge. Message provider 24 may provide a message based on a status indicator or condition code that is received from the appliance, an accessory for the appliance, or the badge. The message provider 24 may change color or emit an audible noise to signify a particular status. For example, message provider 24 may be illuminated with a first color, such as green, to inform a user of a first status message, and may be illuminated with a second color, such as red, to inform a user of a second status message. This configuration can be useful if used with an accessory comprising a water filter, with the message color signifying that the water filter is working properly (i.e. green) or that the water filter needs to be changed (i.e. red).

Message provider 24 may provide a status message based on a first status indicator, and may then enhance the status message based on a second status indicator. For example, message provider 24 may provide a status message based on data regarding an oven timer (a first status indicator), and may then enhance the status message after receiving data regarding a lapse of time where an oven door has remained closed (a second status indicator).

Message provider 24 may also be provided with means for enhancing a message. In one contemplated embodiment, message provider 24 can illuminate a visual message using a source of illumination comprising a light source. Further, message provider 24 itself may include the light source and a panel that includes a message thereon that is only visible when light is applied from the light source. A badge may be configured to selectively illuminate the panel when connected to a light source. Message provider 24 may also include a light diffuser to spread-out or scatter light in some manner so as to provide a message. In another contemplated embodiment, a badge may use a source of illumination to enhance the message provided by the message provider 24. For example, a badge may include a message provider 24 that is illuminated, possibly with one or more different colors, in order to convey a message to the user.

Additional Component for Badge

Additional component 25 of a badge provides an additional functionality to the badge, an appliance, or an accessory for the appliance. Component 25 may be an electrical or mechanical component.

Examples of the component 25 include, but are not limited to, a controller, a battery, a processor, a memory, an electronic signal transmission device, a transformer, a photo-transmission electronic, a microphone, a signal transmission media such as a wire or antenna, a wireless transceiver, a storage module for storing computer readable instructions, a sensor (such as to detect infrared light, visible light, motion, sound, an object in proximity, or the like), a barcode scanner to scan a barcode of an article and work in conjunction with an inventory system, a consumables reader, or a data storage unit that includes data and/or computer readable medium. For example, a data storage unit may include data about a consumable and instructions related to a cycle of operation.

Component 25 may include hardware and software for sending, receiving, storing, and performing one or more computer readable instructions, such as those to selectively provide a message through message provider 24. Furthermore, component 25, as well as the appliance in general, may include hardware and software for communicating with peripheral devices either wirelessly or through a direct connection, such as through one or more service connectors. Examples of such peripheral devices include a computer, a cell phone, a digital music player, as well as any other consumer electronic device. In addition, component 25, as well as the appliance in general, may include hardware and/or software for communication with other appliances that are part of an appliance network. Badge 20, for example, may receive messages, status updates, or data from one or more appliances in a network via the component 25.

Accessory for Appliance

An accessory may provide an additional function that enhances, supplements, regulates or monitors the functionality of the appliance. The accessory may be directly related to the function of the appliance. Alternatively, an accessory may provide a function unrelated to the function of the appliance but related to tasks that users of the appliance are be engaged in when in the vicinity of the appliance or when using the appliance, such as devices proving information, entertainment or communication.

An accessory may facilitate communication between an appliance and a badge or a second accessory. An accessory may be configured to communicate at least one service from appliance to a badge or to a second accessory. For example, an accessory may receive a service from the appliance, such as power or data, and supply it to the badge or a second accessory.

As discussed above, an accessory may be provided with one or more functional components that can provide an additional function to the accessory itself or to an appliance or badge associated with the accessory. A functional component of an accessory can be, but is not limited to, a an antenna, a wireless radio, a wireless transceiver, a controller, a memory, a processor, a consumables reader, a battery, an electronic signal transmission device, a water filter/purifier, an air filter/purifier, a storage module for storing computer readable instructions, a sensor that detects infrared light, visible light, motion, sound, an object in proximity, etc., and a barcode reader.

In one example, an accessory may be used in conjunction with a cycle of operation of the appliance. The accessory may enhance or alter the cycle of operation, or the accessory may be configured to communicate a new cycle of operation to a controller of the appliance.

In another example, an accessory may be a data device such as a service key permitting access to diagnostic and servicing functions in the appliance control system, or a data device containing software updates for the appliance or facilitating an operational cycle of an appliance.

In another example, an accessory may provide a function relating to one or more articles in a cavity of the appliance, such as a device for reading or sensing data from the articles or their container, for opening the container, for packaging the article, or for sealing the container. The accessory may include a functional component for processing the articles such as by heating cooling, washing, cutting, grinding, or mixing the article.

In another example, an accessory may be a device for providing a sales demo or product usage information. Such a device may communicate with the appliance to provide a simulation of the operation of the appliance through a cycle or simulation of the control sequences of an appliance control operation.

In another example, an accessory may be a digital picture frame that receives power from an appliance through a service interface.

In another example, an accessory includes a functional component comprising a consumables reader or a data storage unit that includes data and/or computer readable instructions. For example, a data storage unit may include data about a consumable and/or instructions for using the consumable in relation to a cycle of operation.

In another example, an accessory includes a functional component comprising a barcode scanner that can scan a barcode of an article, and work in conjunction with an inventory system, or the like, to inventory the article.

In another example, an accessory includes a first functional component comprising a water filter configured to remove contaminants from an external water supply, such as water supply 17 shown in FIG. 3, and provide the filtered water to an ice/water dispenser, such as dispenser 16. The accessory can further include a second functional component comprising a controller. The controller can monitor the status of the water filter, and provide a condition code based on a status of the water filter to another device, such as an appliance or badge. Badge may then provide a message based on the condition code, such as via the message provider 24.

Still other examples of accessories include an energy controller, a voice module, and a smart coupler and cable, as described in U.S. patent application Ser. No. 11/930,299, filed on Oct. 31, 2007, and entitled “Network for Communicating Information Related to a Consumable to an Appliance,” the contents of which are hereby incorporated by reference in their entirety.

The following clauses define preferred aspects of the invention. The clauses are not claims of this application (which are presented in a separate section headed “Claims”), but are part of the disclosure:

A1. A badge for an appliance that selectively performs a physical operation on a article, the badge having a body sized to substantially cover a service interface of an appliance, an attachment mechanism fixed to the body to detachably secure the body in close proximity to a visible surface of an appliance and to substantially cover the service interface, and an antenna disposed within at least a portion of the body to facilitate wireless communication between the body and one of an appliance and another communication node.

A2. The badge of clause A1, further comprising a first badge service interface that is complementary to the service interface of the appliance for coupling therewith.

A3. The badge of clause A2 wherein the appliance comprises a second service interface for providing service to an electronic appliance accessory different from the badge, and the body is sized to substantially also cover the second service interface when the attachment mechanism is secured to the visible surface of the appliance and when the accessory is coupled to the second service interface.

A4. The badge of clause A3 wherein the badge comprises a third service interface for coupling to the electronic appliance accessory and the accessory includes a forth service interface compatible with the third service interface wherein the badge can communicate a first service with the appliance using the first based service interface when the attachment mechanism is secured to the visible surface of the appliance and wherein the badge can communicate a second service with one of the appliance and the accessory when the accessory is coupled to the second service interface and the third service interface is engaged with the forth service interface.

A5. The badge of clause A2, further comprising a detachable shaft having a second service interface for connecting with the appliance service interface and a third service interface for connecting to the first badge service interface wherein the badge can receive a service from the shaft when the first badge service interface is attached to the third service interface and when the second service interface is connected to the appliance service interface and wherein the badge can receive a service from an accessory when the shaft is detached from the badge and the accessory is connected to the appliance service interface and the first badge service interface is connected to the accessory.

A6. The badge of clause A2 wherein the badge comprises circuitry for handling radio frequency signals received by the antenna and for communicating the signals with the first badge service interface wherein a radio operably coupled to the first badge service interface can receive the signals.

A7. The badge of clause A1 and further comprising a communication link between the antenna and the badge service interface.

A8. The badge of clause A1 wherein the attachment mechanism comprises a shaft extending from the body, and the badge service interface is formed in the shaft.

B1. An appliance configured to operably couple with an electronic accessory, the appliance including a visible surface having an opening, a recess extending from the opening into the appliance, the recess being configured to selectively admit an accessory for the appliance and substantially enclose the accessory, a first electronic service interface disposed in the recess for selectively providing a service to the accessory when the accessory is received within the recess, and a cover movably mounted to the appliance, wherein the cover has an electronic function and an interface for selectively engaging one of the first electronic service interface and the accessory whereby to selectively cover and expose the opening and to engage one of the first electronic service interface and the accessory when covering the opening.

B2. An appliance including a visible surface on the exterior of the appliance having an opening, a cover selectively engaging the opening to selectively cover the opening, a recess extending from the opening of the visible surface, the recess selectively admitting an accessory for the appliance and substantially enclosing the accessory when the accessory is admitted, a first electrical connector disposed in the recess and alternatively providing a first electrical service to the accessory; and a second electrical connector disposed locally to the recess for providing a second electrical service to one of the cover, the accessory, and a badge.

B3. The appliance of clause B1 or B2 wherein the second electronic interface is engageable with a third electronic interface of the accessory when the accessory is disposed in the recess.

B4. The appliance of clause B1 or B2 wherein the electronic function is to provide a message.

B5. A system including an appliance configured to perform a physical operation on a article, a visible surface on the exterior of the appliance, an opening in the visible surface, a recess in the appliance extending from the opening and sized to receive an accessory for the appliance, a service interface provided in the recess and spaced distally from the opening, and selectively providing a service to the accessory, and a cover coupling with the service interface to close the recess, wherein when the cover is coupled to the service interface in the absence of the accessory, the service interface provides the service to the cover.

B6. The system of clause B5 wherein the cover has a service interface engageable with the service interface provided in the recess and the service interface of the cover is engageable with a service interface of the accessory when the accessory is disposed in the recess.

C1. A badge for an appliance, the badge including a body having a front side and a back side, an attachment mechanism on the back side of the body and configured to detachably secure the body to a visible surface of an appliance, a message provider on the front side of the body to communicate a message, a first communication system for receiving an identifier, and a controller operably coupled to the message provider and the first communication system and having access to a plurality of messages, wherein the controller can receive the identifier from the first communication system, select at least one message from the plurality of messages based on the identifier, and provide a control signal to the message provider based at least in part on the identifier to communicate the selected at least one message via the message provider.

C2. The badge of clause C1 wherein the first communication system includes circuitry for receiving wireless messages, a first software for processing the messages, and a second software for communicating a portion of data received in the message with the controller.

C3. The badge of clause C2 further comprising a second communication system that includes circuitry for receiving messages from the appliance, a third software for processing the messages, and a fourth software for communicating a portion of data received in the message with the controller.

C4. The badge of clause C3 wherein the data includes the identifier.

C5. The badge of clause C3 wherein the second communication system further includes circuitry for receiving wireless messages, a first software for processing the messages, and a second software for communicating a portion of data received in the message with the controller.

C6. The badge of clause C1 wherein the identifier is received from the appliance.

C7. The badge of clause C1, further comprising a second communication system for receiving wirelessly broadcasted messages.

C8. The badge of clause C1 wherein the plurality of messages includes wirelessly broadcasted messages and the controller is operably coupled to the second communication system for access to the wirelessly broadcasted messages.

C9. The badge of clause C1 wherein the identifier is a status of one of the appliance and the badge.

C10. The badge of clause C1 and further comprising a logo on the front side for one of the appliance and the accessory.

C11. A badge for displaying a logo for an appliance, the badge including a body configured to cover an appliance service interface of the appliance, a badge service interface for removably coupling the badge to the appliance service interface to form a service pathway for receiving power from the appliance, a message receiver capable of receiving messages, and a message provider associated with the body, wherein the message provider can simultaneously communicate at least one logo for the appliance and a message received by the message receiver.

C12. The badge of clause C11 wherein the message receiver is coupled to the badge service interface to receive messages from the appliance.

C13. The badge of clause C11 wherein the message receiver is a wireless message receiver that receives wirelessly broadcasted messages.

C14. The badge of clause C11 wherein at least one of the message receiver and the message provider are coupled to the service pathway to receive power from the appliance.

C15. A system including an appliance having a visible surface, wherein the appliance is configured to perform a physical operation on an article, a control system disposed within the appliance, a first service interface operably connected to the control system and selectively providing a service, an accessory operably connected to the first service interface, and a badge at the visible surface, detachably engaging the appliance, and having a message provider, wherein the message provider provides a message based on a status of one of the accessory and the control system.

C16. The system of clause C15 wherein the badge is detachably engageable to first service interface.

C17. The system of clause C15 wherein the appliance includes a second service interface at the visible surface having a mechanical coupling interface for detachably engaging the badge wherein the second service interface provides one of a power, data, acoustic, motion, and illumination service to the badge when the badge is engaged with the mechanical coupling interface.

C18. The system of clause C15 wherein the badge has a second service interface engageable with the first service interface provided in the recess and the second service interface is engageable with a third service interface of the accessory.

C19. The system of clause C15 wherein the badge comprises a service interface that couples with the first service interface and the message provider is coupled to the service interface of the badge to receive messages from the appliance via the first service interface.

D1. An appliance configured to operably couple with an electronic accessory, the appliance including a visible surface on the appliance at an opening, a recess extending from the opening of the visible surface, the recess configured to selectively admit at least a portion of an accessory for the appliance and substantially enclosing the accessory when the accessory is admitted, a first electronic service interface disposed in the recess and selectively providing a service to the accessory when the accessory is received within the recess, and a badge having indicia communicating a message and having an interface selectively engaging the recess to selectively cover and expose the opening.

D2. The appliance of clause D1 wherein the second electronic service interface is engageable with a third electronic service interface of the accessory when the accessory is disposed in the recess.

D3. The system of clause D1 wherein the badge uses the service provided by the first electronic service interface to communicate the message.

D4. A system includes an appliance having a visible surface, a service interface provided on the appliance accessible from the visible surface and communicating at least one electrical service, an accessory coupled to the service interface and receiving electrical service from the service interface, and a badge selectively providing a message and substantially covering the accessory.

D5. A system includes an appliance performing a physical operation on an article, a visible surface on the exterior of the appliance, a recess formed in the visible surface, the recess alternatively admitting at least a portion of an accessory for the appliance and selectively coupling with a badge, a service interface disposed in the recess and alternatively providing a service to the accessory and the badge, and a badge mounted to the appliance at the recess, wherein the badge uses the service provided by the service interface to provide a message.

D6. The system of clause D4 or D5 wherein the service interface of the badge is engageable with a service interface of the accessory when the accessory is disposed in the recess.

E1. A functional device for use with a host device having a housing with an exposed surface, an elongated recess in the housing extending from an opening in the exposed surface and having a base, and a first interface at the base of the elongated recess, the functional device including an elongated shank having a first end and a second end, and capable of being inserted in the recess, a first functional component disposed in the elongated shank, a second interface disposed at one end of the elongated shank and engageable with the first interface, the second interface being in operable communication with the first functional component to communicate a service between the first interface and the first functional component, a head formed at the second end of the elongated shank, the head being engageable with the housing to selectively close the opening of the recess when the second interface is engaged with the first interface to place at least an exposed portion of the head beyond the exposed surface, and an antenna disposed at least partially in the exposed portion of the head, the antenna being in operable communication with the first functional component.

E2. A functional device for use with a host device having a housing with an exposed surface, an elongated recess in the housing extending from an opening in the exposed surface and having a base, and a first interface at the base of the elongated recess, the functional device including an elongated shank having a first end and a second end, and capable of being inserted in the recess, a first functional component disposed in the elongated shank, a second interface disposed at one end of the elongated shank and engageable with the first interface, the second interface being in operable communication with the first functional component to deliver a service from the first interface to the first functional component, a head formed at the second end of the elongated shank, the head being engageable with the housing to selectively close the opening of the recess when the second interface is engaged with the first interface to place at least an exposed portion of the head beyond the exposed surface, and a programmable display disposed at least partially in the exposed portion of the head, the programmable display being in operable communication with the first functional component.

E3. A functional device for use with a host device having a housing with an exposed surface, an elongated recess in the housing extending from an opening in the exposed surface and having a base, and a first interface at the base of the elongated recess, the functional device including an elongated shank having a first end and a second end, and capable of being inserted in the recess, a first functional component having a microprocessor disposed in the elongated shank, a second interface disposed at one end of the elongated shank and engageable with the first interface, the second interface being in operable communication with the first functional component to deliver a service from the first interface to the first functional component, a head formed at the second end of the elongated shank, the head being engageable with the housing to selectively close the opening of the recess when the second interface is engaged with the first interface to place at least an exposed portion of the head beyond the exposed surface, and a second functional component disposed at least partially in the exposed portion of the head, the second functional component being in operable communication with the first functional component.

F1. A method of conveying an advertising message, the method including providing an appliance with a service interface and a badge, wherein the badge is detachably connected to the service interface and substantially covers the service interface and wherein the badge is further configured to convey a message, and communicating an advertising message to the service interface wherein the advertising message contains information about a consumable for use with the appliance so that the badge will convey the advertising message only when the badge is connected to the service interface.

F2. A method of promoting a purchase of an accessory for an appliance, the method including providing an appliance with a service interface for providing a service to one of an accessory and a badge, providing a badge configured to detachably connect to the service interface and receive the service, and to substantially cover the service interface, and selectively providing a message via the badge when the badge is connected to the service interface, the message promoting an acquisition of an accessory that can receive the service from the service interface.

G1. A badge for an appliance having a visible surface and an electrical service interface disposed on the visible surface, wherein the appliance performs a physical operation on an article, the badge including a body sized to substantially cover the electrical service interface, an attachment mechanism fixed to the body to detachably secure the body to the visible surface, and a message provider for conveying a message that promotes an acquisition of a device capable of removably coupling with the electrical service interface and receiving a service therefrom.

G2. The badge of clause G1, further comprising a service interface on the body configured to couple with the appliance, and a controller that is coupled to the service interface to receive data via the service interface.

G3. The badge of clause G1 wherein the data is a status of the appliance.

G4. The badge of clause G1, further comprising a logo on the body for one of the appliance and the device.

G5. The badge of clause G1, further comprising a second service interface wherein the first service interface is useable for connection to an accessory wherein when the accessory is connected to the appliance the accessory communicates at least one service with an appliance and the accessory communicates at least one service with the badge and wherein the second service interface is attachable to the visible surface and communicates at least one service directly with the appliance when the second service interface is attached to the visible surface.

G6. The badge of clause G5 wherein the at least one service originates from the appliance.

G7. The badge of clause G1, further comprising a message receiver that receives messages from the appliance and is coupled to the message provider.

G8. The badge of clause G7 wherein the message receiver is a wireless message receiver that receives wirelessly broadcasted messages.

G9. A system including an appliance having a visible surface and an electrical service interface disposed on the visible surface, wherein the appliance performs a physical operation on an article and a badge, which includes a body substantially covering the electrical service interface, an attachment mechanism fixed to the body and detachably securing the body to the visible surface, and a message provider providing a message, wherein the message promotes an acquisition of a device that removably couples with the electrical service interface and receives an electrical service therefrom.

G10. The system of clause G9 wherein the badge is the badge from any of clauses G1-G8.

G11. The system of clause G9 wherein the electrical service interface provides a service comprising one of electrical power and data.

G12. The system of clause G9 wherein the door comprises a recess, the electrical service interface is provided in the recess, and the badge is at least partially received in the recess.

G13. The system of clause G12, wherein the badge communicates with the control system and provides the message based on the data.

H1. A system including an appliance performing a physical operation on an article and having a visible surface and an appliance controller, a service interface facilitating communication with the appliance controller, and a badge. The badge includes a body substantially covering the service interface, an attachment mechanism fixed to the body and detachably securing the body to the visible surface, a logo for the appliance provided on the body, a message provider, and a badge controller disposed within the body, wherein the badge controller is in communication with the appliance controller via the service interface, and selectively providing a message via the message provider based in part on the communication with the appliance controller.

H2. The system of clause H1 wherein the service interface is disposed in a recess of the appliance and the message includes a promotion for the acquisition of an accessory to be place in the recess and connected to the service interface.

H3. The system of clause H2 wherein the accessory will displace the badge when it is connected to the service interface.

H4. The system of clause H2 wherein the accessory will displace the communication between the badge and the appliance with communication between the accessory and the appliance when the accessory is connected to the service interface.

H5. The system of clause H1 wherein the message promotes the acquisition of an accessory for the appliance, the system further comprising a data store of information comprising at least two accessory identifiers each for an accessory and at least one message for each accessory corresponding the at least two identifiers.

H6. The system of clause H5 wherein the data store further comprises at least two appliance identifiers each for an appliance, and at least one data key relating each of the at least two appliance identifiers to the at least two accessory identifiers, wherein the message provider can provide the appropriate accessory acquisition messages based on the at least tow appliance identifiers and the identifier of the appliance.

H7. A badge including a body having a front side and a back side, an attachment mechanism fixed to the back side of the body to detachably secure the body to a visible surface of an appliance, a message provider on the front side of the body, and a controller configured to selectively receive operational information from an appliance and provide a control signal to the message provider based in part on the received operational information from the appliance, wherein the message provider facilitates communicating a message in response to the control signal.

H8. The badge of clause H7, further comprising a service interface on the body that couples with the appliance, and the controller is coupled to the service interface to receive operational information via the service interface.

H9. The badge of clause H7 wherein the operational information is a status of the appliance.

H10. The badge of clause H7 wherein the message provided by the badge varies based on the control signal.

H11. A badge including a body configured to substantially cover a service interface of an appliance that selectively provides a service to an accessory and the badge, an attachment mechanism provided on the body to detachably secure the body to a visible surface of the appliance, a coupling interface for removably coupling the body to the service interface, a message provider on the body for providing an advertisement message, and a service pathway connecting the coupling interface to the message provider to deliver the service to the message provider, wherein the message provider provides the advertisement message only when the body is coupled to the service interface.

H12. The badge of clause H11 wherein the coupling interface comprises a service interface that couples with the service interface of the appliance, and the message provider is coupled to the service interface of the badge to receive messages from the appliance.

H13. The badge of clause H11 and further comprising a message receiver for receiving messages coupled to the message provider.

H14. The badge of clause H13 wherein the message receiver includes an antenna for detecting broadcast wireless advertisement messages and further includes a first software for processing the broadcast advertisement messages and a second software for sending the advertisement messages to the message provider.

H15. The badge of clause H14 further comprising at least one code for matching to at least one code included in the broadcast advertisement messages wherein the one of the first and second software discards the message when the at least one code does not match the at least one code included in the broadcast advertisement messages.

H16. The badge of clause H15 wherein the code is one of a zip code, a location code, a store code representing a particular vendor or store owned by a vendor, a code representing demographic information, and a subscription code specifying a particular class of advertisement message wherein the sender of the message can put at least one code in the message to target the message for a subset of badges.

I1. An appliance for selectively performing a physical operation on a article, the appliance including a visible surface on the exterior of the appliance having an opening, a recess extending from the opening and having a proximal end adjacent the visible surface of the appliance and a distal end opposite the proximal end, a first service interface at the distal end adapted to mechanically receive and connect to an electronic device, and a second service interface for connecting to an antenna disposed external to the appliance to enable radio frequency communications when the electronic device is connected to the first service interface and the antenna is connected to the second service interface, wherein the first service interface comprises a first portion for connecting the antenna to the electronic device and a second portion for delivering power from the appliance to the electronic device when the electronic device is connected to the service interface.

I2. An appliance for selectively performing a physical operation on a article, the appliance including a visible surface on the exterior of the appliance having an opening, a recess extending from the opening and having a proximal end adjacent the visible surface of the appliance and a distal end opposite the proximal end, a service interface at the distal end adapted to mechanically receive and connect to an electronic device, and an antenna disposed within the appliance to enable radio frequency communications when the electronic device is connected to the service interface, wherein the service interface comprises a first portion for connecting the antenna to the electronic device and a second portion for delivering power from the appliance to the electronic device when the electronic device is connected to the service interface.

I3. The appliance according to clause I2, and further comprising a cover for selectively engaging the recess to selectively cover and expose the opening.

I4. The appliance according to clause I3 and further comprising a second antenna disposed substantially within the cover.

I5. The appliance of clause I2 further comprising a controller disposed within the appliance and configured to facilitate a useful cycle of operation, wherein the service interface is operatively coupled to the controller and the service interface is further configured to provide a communication link between the antenna and the controller.

I6. The appliance of clause I2 wherein the service interface has a first portion connected to the antenna and a second portion configured to accept a radio.

I7. A system including an appliance having a visible surface and an opening in the visible surface, a service interface provided in the opening, an antenna having a first portion connected to the service interface and disposed behind the visible surface, and a second portion disposed adjacent to the opening, and a cover configured to selectively substantially close the opening and cover the service interface.

I8. The system of clause I7 wherein the first portion is a conductive material connecting the service interface to the second portion.

I9. A system including an appliance having a generally planar conductive surface partially defining an interior and an exterior, a transmitter disposed within the interior, an antenna connected to the transmitter, the antenna having a portion at least partially exposed to the exterior, and a cover substantially covering the portion.

I10. A system including an appliance selectively performing a physical operation on an article and having a visible surface, an antenna disposed near the visible surface and having at least a portion visible from an exterior of the appliance, and a cover substantially covering at least the visible portion.

I11. The system of clause I10 wherein the appliance comprises a user interface or user interface console and the cover is comprised by the user interface or user interface console.

I12. The system of clause I10 wherein the appliance comprises at least one user interface component the cover is partially transparent and covers the at least one user interface component.

I13. The system of clause I12 wherein the cover is glass.

I14. The system of clause I12 wherein the cover has an outside plane external to the appliance and an inside plane facing toward the appliance and the antenna is affixed to the inside plane.

I15. The system according to clause I10, further comprising a second antenna disposed substantially within the cover.

I16. The system of clause I10, further comprising a controller disposed within the appliance and configured to facilitate a useful cycle of operation, wherein the service interface is operatively coupled to the controller, and the service interface is further configured to provide a communication link between the antenna and the controller.

J1. An appliance including a body having a first visible surface and a cavity for selectively receiving an article, a door for providing access to the cavity, the door having a second visible surface, a control system for facilitating the performance of a physical operation on an article received in the cavity, and a service interface disposed on at least one of the first and second visible surfaces, wherein the service interface includes a first service connector to connect to an accessory and a second service connector to connect to one of a badge and an antenna module.

J2. The appliance of clause J1 further comprising the antenna module operably coupled to the service interface wherein the accessory or the badge comprising a receiver can operably couple to the antenna module when the accessory or the badge is operably coupled to the service interface for facile communications associated with signals received from the antenna module.

J3. The appliance of clause J2 wherein the antenna module includes an antenna.

J4. The appliance of clause J3 wherein the antenna module further includes at least one of an impedance matching circuit, a filter, a noise filter, and a signal amplifier.

J5. The appliance of clause J1 further comprising a pathway connecting the first service connector to the second service connector, whereby the pathway enables communications between the antenna module and the accessory when the accessory is connected to the first service connector and the antenna module is connected to the second service connector.

J6. The appliance of clause J1 further comprising the badge and the badge comprises the antenna module.

J7. The appliance of clause J6 wherein the antenna module includes an antenna.

J8. The appliance of clause J7 wherein the antenna module further includes at least one of an impedance matching circuit, a filter, a noise filter, and a signal amplifier.

J9. The appliance of clause J1 wherein the first service connector provides a first service to the accessory and the second service connector provides a second service to the badge.

J10. The appliance of clause J9 wherein the first and second services are the same.

J11. The appliance of clause J9 wherein the first and second services are different.

J12. The appliance of clause J1, further comprising a recess formed in the door, and the service interface is at least partially disposed in the recess.

J13. The appliance of clause J12 wherein the recess is configured to receive at least a portion of the accessory and further wherein the badge covers at least a portion of the recess.

J14. The appliance of clause J1 wherein the badge provides a message.

J15. The appliance of clause J14 wherein the badge is configured to receive input from at least one of the appliance and the accessory, and the message is based on the input.

J16. The appliance of clause J14 wherein at least one of the appliance and the accessory is configured to provide a condition code to the badge, and the message is based on the condition code.

J17. The appliance of clause J1, further comprising the accessory and the badge.

J18. The appliance of clause J1, further comprising a service pathway connecting the first and second service connectors, wherein the service pathway is configured to facilitate communication of a service.

J19. The appliance of clause J1 wherein the accessory includes a processor, a memory, a wireless transceiver, and a computer readable medium, the badge includes an antenna, and the accessory and the badge are configured to detachably connect to one another such that the antenna is operably coupled to the transceiver.

J20. The appliance of clause J1 wherein the badge includes a processor, a memory, a wireless transceiver, and a computer readable medium, the accessory includes an antenna, and the accessory and the badge are configured to detachably connect to one another such that the antenna is operably coupled to the transceiver.

J21. The appliance of clause J1 wherein the accessory includes a processor, a memory, and a computer readable medium, and the badge includes a message provider coupled to a message generator and is configured to provide a message based on a status of the accessory.

J22. An appliance for selectively performing a physical operation on an article and operably coupling with a first and a second accessory, the appliance including a visible surface on an exterior of the appliance and having an opening, a recess extending into the appliance from the opening, a first service interface disposed in the recess to facilitate selectively providing a service to at least one of the first and second accessories, a service providing component for selectively providing a service to the first service interface when the first accessory is coupled to the first service interface, and a message generator providing a promotional message relating to the first accessory when the second accessory is coupled to the first service interface.

J23. The appliance of clause J22 wherein the first service interface further comprises a service connector that alternatively couples with the first and second accessories.

J24. The appliance of clause J22, further comprising a second service interface for selectively providing a service to at least one of the first and second accessories.

J25. The appliance of clause J24 wherein the first service interface provides a first service to the first accessory and the second service interface provides a second service to the second accessory.

J26. The appliance of clause J22 wherein the first service interface provides a first service to the first accessory and a second service to the second accessory.

J27. The appliance of clause J26 wherein the first and second services are the same.

J28. The appliance of clause J26 wherein the first and second services are different.

J29. The appliance of clause J22 wherein the appliance is a refrigerator having a cabinet and a door, and the visible surface is formed in the door.

J30. The appliance of clause J22 wherein the recess is configured to receive at least a portion of the second accessory and further wherein the first accessory is adapted to couple with the service interface to cover at least a portion of the recess.

J31. The appliance of clause J22 and further comprising a controller disposed within the appliance and configured to provide a signal to the message generator.

J32. The appliance of clause J31 wherein the promotional message is at least one of selected, displayed and enhanced in response to the signal.

J33. The appliance of clause J22 and further comprising a message provider coupled to the message generator for providing the promotional message.

J34. The appliance of clause J22 wherein the message generator is configured to receive input from at least one of the appliance, the first accessory, and the second accessory, and the promotional message is based on the input.

J35. The appliance of clause J22 wherein at least one of the appliance, the first accessory, and the second accessory is configured to provide a condition code to the message generator, and the promotional message is based on the condition code.

J36. The appliance of clause J22 wherein the message generator is further configured to communicate with the appliance via the service interface, and further configured to provide the promotional message based at least in part on data received from the appliance.

J37. The appliance of clause J22, further comprising the first and second accessories.

J38. The appliance of clause J22, further comprising a service pathway connecting the first and second accessories, wherein the service pathway is configured to facilitate communication of a service.

J39. The appliance of clause J22 wherein the second accessory includes a processor, a memory, a wireless transceiver, and a computer readable medium, the first accessory includes an antenna, and wherein the first and second accessories are configured to detachably connect to one another such that the antenna is operably coupled to the transceiver.

J40. The appliance of clause J22 wherein the first accessory includes a processor, a memory, a wireless transceiver, and a computer readable medium, the second accessory includes an antenna, and wherein the first and second accessories are configured to detachably connect to one another such that the antenna is operably coupled to the transceiver.

J41. The appliance of clause J22 wherein the first accessory includes a processor, a memory, and a computer readable medium, the second accessory includes a message provider coupled to the message generator, and wherein the second accessory is configured to provide a message based on a status of the first accessory.

J42. The appliance of clause J22 wherein the first accessory comprises a functional component that provides an additional capability to the appliance and the functional component is configured to provide a condition code to the message generator, and the message generator is configured to provide the promotional message based on the condition code.

J43. The appliance of clause J22 wherein the second accessory comprises a cover.

J44. The appliance of clause J22 wherein the service providing component is one of a service connector and a service line.

J45. The appliance of clause J22 wherein the service providing component is an electrical power component, a data component, a mechanical power component, a mechanical motion component, a thermal energy component, an illumination component, a sound or acoustic component, a fluid power component, or a substance component.

J46. The appliance of clause J45 wherein examples of electrical power components include an electrical connector, a battery, an electrical power line and a wireless power component, examples of data components include a data connector, a data line and a wireless data component, examples of mechanical power components include a mechanical power connector and a rotating member, examples of mechanical motion components include a mechanical motion connector and a rotating member, examples of thermal energy components include a thermal energy connector, a fluid line, and a heater, examples of illumination components include an illumination connector, a light bulb, an LED, a light pipe, a light transmitter, a light receiver, and an opto-isolator, examples of sound or acoustic components include a sound or acoustic connector, a sound generator, and a speaker, examples of fluid power components include a fluid power connector, and a fluid line, and examples of substance components include a substance connector, a fluid line, and a substance dispenser.

K1. An accessory for an appliance having a service interface and a badge selectively engageable with the service interface to at least partially cover the service interface, the accessory including a body comprising a functional component, wherein the body is configured to be selectively received within the service interface, a first service connector disposed on the body to operably couple to the service interface, and a second service connector disposed on the body to operably couple to the badge.

K2. The accessory of clause K1 wherein the appliance furthers comprises an antenna module operably coupled to the service interface and the service interface provides a radio frequency signal from the antenna to the accessory when the accessory is coupled to the first service connector; the accessory further comprising a radio frequency receiver and a service pathway connecting the first service connector component to the radio frequency receiver, whereby service communications between the radio frequency receiver and the antenna module are established when the accessory is connected to the first service connector and the antenna receives and propagates the radio frequency signal across the service pathway.

K3. The accessory of clause K2 wherein the antenna module includes a connection interface for connecting to an antenna.

K4. The accessory of clause K1 wherein the accessory comprises and antenna module and a service pathway for operably connecting the antenna module to the first service connector wherein the antenna module can receive radio frequency signals and propagate them onto the service pathway to establish facile communications between at least one of the appliance and the accessory and a source of radio frequency signal.

K5. The accessory of clause K1, further comprising a radio module.

K6. The accessory of clause K5 wherein the antenna module is coupled to the radio and the radio is coupled to the first service connector for interaction with the appliance.

K7. The accessory of clause K1 wherein the appliance comprises a radio module.

K8. The accessory of clause K7 wherein the radio module is an interface for a radio.

K9. The accessory of clause K7 wherein the radio module comprises a radio.

K10. The accessory of clause K7 wherein the radio is in communication with the appliance control system.

K11. An accessory for an appliance having a recess, the accessory including a body comprising a first end, a second end opposite the first end, and a functional component, wherein the body is selectively removably receivable within the recess of the appliance, a first service connector disposed on the body proximate to the first end to selectively operably couple to a complimentary third service connector in the recess, and a second service connector disposed on the body proximate to the second end to selectively operably couple to a complimentary fourth service connector of a cover.

K12. The accessory of K11 wherein the cover comprises an antenna module and the fourth service connector provides a radio frequency signal to the accessory when the second service connector is coupled to the fourth service connector.

K13. The accessory of K12 wherein the antenna module comprises an antenna, an amplifier, and a filter.

K14. The accessory of clause K1 or K11 wherein the first service connector communicates a first service to the accessory, and the second service connector communicates a second service to the badge.

K15. The accessory of clause K14 wherein the first service is the same as the second service.

K16. The accessory of clause K14 wherein the first service is different than the second service.

K17. The accessory of clause K14 wherein the first service is fluid communication and the second service is data communication.

K18. The accessory of clause K1 or K11 further comprising a service pathway connecting the first service connector to the second service connector, wherein the service pathway is configured to facilitate communication of a service between the appliance and the badge.

K19. The accessory of clause K1 or K11 wherein the first service connector facilitates fluid exchange between the functional component and the appliance.

K20. The accessory of clause K1 or K11 further comprising a processor, a memory, and a computer readable medium for selectively providing data to the badge via the second service connector.

K21. The accessory of clause K1 or K11 wherein the body is substantially cylindrical, with a proximal end and a distal end.

K22. The accessory of clause K21 wherein the first service connector is provided on the proximal end.

K23. The accessory of clause K21 wherein the second service connector is provided on the distal end.

L1. A system including an appliance for selectively performing a physical operation on an article and having a visible surface, a recess formed in the visible surface, a cover for selectively covering the recess, a service interface positioned within the recess and configured to communicate at least one service, and an accessory that includes a first service connector and a second service connector, wherein the first service connector removably couples to the service interface and communicates at least a first service with the accessory and the second service connector couples to the cover and communicates at least a second service with the cover.

L2. A system including an appliance for selectively performing a physical operation on an article, a visible surface on an exterior of the appliance, a service interface at the visible surface for providing an electrical service to one of an accessory and a badge, and a badge for selectively coupling with the service interface, wherein the badge is configured to removably mount to the appliance in a position to substantially cover the service interface and at least a portion of the visible surface whereby when so mounted and coupled, the badge can use the electrical service to provide a message promoting acquisition of the accessory.

L3. The system of clause L1 or L2 wherein the appliance is a refrigerator having a cabinet and a door and the recess is formed in the door.

L4. The system of clause L1 or L2 wherein one of the appliance, the accessory and the cover includes a processor, a memory, a wireless transceiver, and a computer readable medium, and one other of the appliance, the accessory and the cover includes an antenna that is operably coupled to the transceiver.

L5. The system of clause L1 or L2 wherein the service interface further comprises a service connector that couples with the first service connector.

L6. The system of clause L1 or L2 wherein the cover has a third service connector engageable with the second service connector.

L7. The system of clause L1 or L2 wherein the cover comprises a badge configured to provide a message and the cover is configured to receive input from one of the accessory and the appliance, and the message is based on the input.

L8. The system of clause L1 or L2 wherein the cover comprises a badge configured to provide a message and the accessory is configured to provide a condition code to the cover, and message is based on the condition code.

L9. The system of clause L1 or L2, further comprising an antenna module.

In any of these clauses, unless otherwise noted;

a. any service can comprise one of electrical power, data, mechanical power, mechanical motion, thermal energy, illumination, acoustic, fluid power, radio frequency signal, and substance;

b. any service interface can comprise a service connector. Further, the service connector can be one of an electrical power connector, a data connector, a mechanical power connector, a mechanical motion connector, a thermal energy connector, an illumination connector, a sound or acoustic connector, a fluid power connector, and a substance connector;

c. any service interface can be configured to selectively simultaneously couple with a cover and accessory, or with two accessories;

d. any service interface can provide a communication link, such as between an accessory and an appliance, or between a cover any an appliance;

e. any service interface can be disposed entirely within a recess of an appliance;

f. any appliance can comprise one of a refrigerator, a freezer, a stove, an oven, a range, a microwave, a dishwasher, a clothes washing machine, a clothes dryer, a clothes refreshing machine, a non-aqueous washing apparatus, an air conditioner, a dehumidifier, or any combination thereof;

g. any appliance can perform a physical cycle of operation on an article, and comprise a cavity within the appliance that is configured to selectively receive an article and a door configured to selectively provide access to the cavity. In this case, various features of the appliance can be provided on the door, such as any service interface or recess of the appliance. Also in this case, any cover, unless otherwise noted, can be disposed on the door;

h. any appliance can comprise a recess for receiving one or more accessories. Further, a cover can be at least partially received in the recess;

i. any visible surface of any appliance can comprise a grill configured to be detachably secured to the appliance;

j. any cover can comprise an attachment mechanism for securing the cover. Further, any attachment mechanism, unless otherwise noted, can extend from a back side of the cover. Further, any cover, unless otherwise noted, can comprise a face plate, and the attachment mechanism can comprise a shaft extending from the back side of the face plate. Further, any attachment mechanism, unless otherwise noted, can comprise one of a hinge, a pin, a screw thread, and a mechanical connection;

k. any service interface of a cover can be integrated with an attachment mechanism of the cover;

l. any service interface can have a portion configured to accept a radio;

m. any service interface and/or recess can comprise a substantially flat or planar conductive surface;

n. any cover can comprise one of a receiver, transmitter, an antenna, an electronic display, a message provider, a light generator, a light diffuser, an LED, a sound generator, a tactile event generator, a power source, a holder, a battery, a controller, a transceiver, a memory, a processor, and a computer readable medium;

o. any cover can provide a barrier against the admittance of substance into any recess or service interface associated with the cover;

p. any cover can completely visibly cover any service interface or accessory associated with the cover. Further, any cover can visibly cover at least a portion of any visible surface associated with the cover;

q. any cover can have a portion adjacent to a visible surface of an appliance when the cover engages or covers a service interface or recess of the appliance;

r. any cover associated with an appliance can be pivotally connected to the appliance. Further, if the appliance has a service interface, the cover can be pivotally connected proximate to the service interface;

s. any cover can alternatively couple to a service interface and an accessory;

t. any cover can comprise a service interface. Further, the cover service interface can engage a service interface the appliance, such as a service interface provided with a recess of the appliance;

u. any cover can use a service to provide a message;

v. any cover or badge can comprise indicia communicating a message. Further, the indicia can comprises one of a logo and a message provider;

w. any logo can be for any appliance or accessory. Further, any logo can display a model, a brand, a retailer, or a manufacturer of the appliance or accessory, or any combination thereof;

x. any logo associated with an appliance or accessory can vary based on input from the appliance or accessory;

y. any cover can comprise a message provider for providing a message. Further, the message provider can comprise at least one of: a display for providing the message visually; an audio device for providing the message acoustically; and a refreshable Braille display for providing the message tactilely;

z. any message provider or programmable display can comprises at least one of: a liquid crystal display, a light emitting diode display, a backlit display, a laser, and a vacuum fluorescent display;

aa. any message can comprise one of an advertisement message, an appliance message, a personal message, and a status message;

bb. any message can comprise one of a visible message, an audible message, and a tactile message;

cc. any message can promote the acquisition of an accessory or a cover;

dd. any message can be based on the status of any appliance, any cover, or any accessory. For example, the status can be a status indicator. In one embodiment, the accessory can be a water filter and the message can be based on the status of the water filter;

ee. any message can vary based on input from any associated appliance, cover, or accessory;

ff. any message can be received from any associated accessory, appliance, or controller of the appliance;

gg. any message can have a first status and a second status, wherein the message is enhanced in the second status as compared with the first status;

hh. any message can be enhanced by at least one of: illuminating the message; brightening the message; backlighting the message; supplementing the message; adding color to the message, changing a color of the message, flashing the message, adding a sound to the message, adding information to the message, changing a pitch of the message, changing a size of the message, changing a language of the message, and increasing a volume of the message;

ii. any antenna can comprise at least one of a patch antenna, a slot antenna, a microstrip antenna, a printed antenna, a monopole antenna, a dipole antenna, and a wire antenna;

jj. any antenna or programmable display can be configured for use in at least one of an appliance network, a computer network, a peer-to-peer communication system, a cellular telephone system, and a voice-over-IP (VOIP) system;

kk. any antenna can comprise a retrofit antenna;

ll. any antenna or a portion of an antenna can be embedded in a cover or the body of a cover;

mm. any antenna can have at least a portion that protrudes beyond a plane defined by the visible surface of an appliance. In such an arrangement, the visible surface can comprise an angled corner;

nn. any antenna can propagate a data service;

oo. a radio communication device can be provided. The radio communication device can be coupled to an antenna. The radio communication device can have an interface capable of coupling to an antenna. The radio communication device can be disposed within an appliance, a cover, or the body of a cover;

pp. any cover or body of a cover can substantially visibly cover an antenna. Further, the cover or body may be configured to completely cover the antenna, as well as a portion of a visible surface of an appliance;

qq. any cover or visible surface can be the material property of attenuating a radio frequency signal;

rr. any system or appliance can comprise an accessory, wherein the accessory is configured to removably couple with a service interface and to provide an additional function to the system or appliance;

ss. any accessory can comprise one of a water filter, a water purifier, an air purifier, a motion detector, a transceiver, a wireless transceiver, a microcontroller, a processor, a dispenser, a network interface adapter, a dispenser, a drink dispenser, a chemistry dispenser, and a memory;

tt. any accessory can be configured to provide at least one of a network connection, a new cycle of operation, a maintenance alert, a display, a message, a consumable reading function, a service function, an audio accessory function, a consumable holding function, a resource management, a control function, a sales demonstration function, and a communication link;

uu. any accessory can comprise a functional component that provides an additional capability to an associated appliance;

vv. any functional component can comprise at least one of a water filter, a water purifier, an air purifier, a motion detector, a transceiver, a wireless transceiver, a microcontroller, a processor, a microprocessor, a dispenser, a network interface adapter, and a memory;

ww. any accessory can comprise a processor, a memory, and a computer readable medium. Further, the computer readable medium can selectively providing data to an associated cover, accessory or control system. Further, any message that is provided can be based on the data;

xx. any accessory can selectively replace any cover;

yy. any system or appliance can comprise a control system that facilitates the performance of a physical operation by an associated appliance;

zz. any control system can be operatively coupled to a service interface to provide a communication link between the control system and an accessory or cover;

aaa. any system can comprise a retrofit cover for replacing an existing cover;

bbb. any message can promotes the purchase of at least one of: an accessory, a consumable, an article related to the appliance, an appliance, a resource, a service contract, and a subscription. The consumable can comprise one of a food, a flavor packet, an ingredient, a concentrate, a cosmetic, a medicine, a detergent, an anti-static cloth, a fabric softener, a chlorine bleach, a color-safe bleach, stain-resistance additive, a wrinkle-resistance additive, a water-repellency additive, an insect-repellency additive, a color-fastness additive, a fragrance, an anti-microbial additive, and a filter. The resource can comprises one of water, electricity, gas, and network access. The service contract can comprise one of a maintenance contract and a use assistance contract. The subscription can comprise information about one of the appliance, the badge, an accessory, an article or a consumable;

ccc. any message can inform the user about a coupon, a sale, or a price for an accessory;

ddd. any message can inform the user about instructions for using an accessory or consumable;

eee. any method can further comprise providing one of a message informing a user about a recall, a message containing instructions for using an accessory, a message containing instructions for using a appliance, a message containing an invitation to a forum, a group, or a show, and a browsing, inquiring, querying, or informing function;

fff. any method can further comprise connecting a cover to a service interface after providing the cover;

ggg. any method can further comprise enhancing a message;

hhh. any method can further comprise providing an accessory;

iii. any method can further comprise receiving an operational status of an accessory or an appliance, and providing a message in response to the received operational status;

jjj. any functional device can have a head that is removable from a shank. Further, the second end of the shank includes a third interface and the head includes a forth interface removably engageable with the third interface, wherein the third and forth interface can communicate a service or a variant thereof when the third and forth interfaces are engaged and when the first and second interfaces are engaged. For example, if the service is electrical power, the variant can be a different electrical power originating from the electrical power. In another example, if the service is a data service, the variant can be a radio frequency receivable by an antenna;

kkk. any functional device can include an antenna;

lll. any functional device can include a radio frequency transceiver operably coupled to an antenna. In cases where the service is a radio frequency signal, the radio frequency transceiver can convert the radio frequency signal into digital data;

mmm. any functional device can include a second functional component disposed in the shank or the head;

nnn. any functional device can include a head with a logo;

ooo. any functional device can include a head that has a width greater than the width of the shank;

ppp. any functional device can include a shank that has a length greater than the length of the head;

qqq. any functional device can include an interface disposed on a side of the elongated shank;

rrr. any functional device can include a shank that is substantially cylindrical, with the first end being a proximal end and the second end a distal end. Further, an interface can be provided on the proximal end. Further, the head can be provided on the distal end;

sss. any functional device can include a processor, a memory, and a computer readable medium for selectively providing data. The data can be provided to an interface, an antenna, a programmable display, and/or a functional component;

ttt. any functional device can have a second interface that facilitates fluid exchange between the functional device and the host;

uuu. any functional device can include a service pathway connecting a first functional component to a second interface or second functional component, wherein the service pathway is configured to facilitate communication of a service therebetween;

vvv. any appliance can include controller disposed within the appliance and configured to provide a signal to a cover, wherein a message is at least one of selected, displayed and enhanced in response to the signal;

www. any cover can be configured to communicate with the appliance via a service interface of the appliance, and further configured to provide a message based at least in part on data received from the appliance;

xxx. any appliance or system can include an appliance component communicatively coupled to a service interface of the appliance. For example, the appliance component can be at least one of a controller, a transceiver, a radio, a television, or any combination thereof; and/or;

yyy. any cover can comprise a badge.

With regard to the processes, systems, methods, heuristics, etc. described herein, it should be understood that, although the steps of such processes, etc. have been described as occurring according to a certain ordered sequence, such processes can be practiced with the described steps performed in an order other than the order described herein. It further should be understood that certain steps can be performed simultaneously, that other steps can be added, or that certain steps described herein can be omitted. In other words, the descriptions of processes herein are provided for the purpose of illustrating certain embodiments, and should in no way be construed so as to limit the claimed invention.

Accordingly, it is to be understood that the above description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In summary, it should be understood that the invention is capable of modification and variation and is limited only by the following claims.

All terms used in the claims are intended to be given their broadest reasonable constructions and their ordinary meanings as understood by those skilled in the art unless an explicit indication to the contrary is made herein. In particular, use of the singular articles such as “a,” “the,” “said,” etc. should be read to recite one or more of the indicated elements unless a claim recites an explicit limitation to the contrary.

We claim:

1. A modular system comprising:
an appliance having a visible surface and configured to selectively perform a physical operation on an article;
a first service interface positioned on the visible surface and configured to provide a service;
a cover detachably coupled to the visible surface and disposed to overlie the first service interface;
a controller configured to selectively provide operational instructions to one of the appliance and the cover; and
an antenna provided within the cover and operably connected to the controller.

2. The modular system of claim 1 wherein the appliance comprises a cavity that is configured to selectively receive an article and a door configured to selectively provide access to the cavity, wherein the first service interface is provided on the door.

3. The modular system of claim 1 wherein the visible surface is an angled corner and the antenna is positioned such that at least a portion of the antenna protrudes beyond a plane defined by the visible surface.

4. The modular system of claim 1, further comprising a communication node, wherein the antenna provides wireless communication between the controller and the communication node.

5. The modular system of claim 4 wherein the communication node is separate from the appliance.

6. The modular system of claim 1 wherein the cover comprises a body sized to substantially overlie the first service interface of the appliance and an attachment mechanism fixed to the body to detachably secure the body in close proximity to the visible surface of the appliance and to substantially overlie the first service interface.

7. The modular system of claim 1 wherein the cover further comprises a second service interface that is complementary to, and couples with, the first service interface.

8. The modular system of claim 1, further comprising a radio communication device coupled to the antenna and disposed within one of the appliance and the cover.

9. The modular system of claim 8 wherein the radio communication device comprises circuitry for communicating radio frequency signals received by the antenna.

10. The modular system of claim 8, wherein the radio communication device comprises at least one of a transceiver, a radio, a television, a computer, an information display device, a telecommunications device, a memory storage device, an energy-measuring device, and any combination thereof, communicatively coupled to the first service interface.

11. The modular system of claim 1 wherein the antenna is embedded in the cover.

12. The modular system of claim 1 wherein the controller is operably coupled with the first service interface and configured to control the physical operation.

13. The modular system of claim 12 wherein the first service interface provides a communication link between the controller and the antenna.

14. The modular system of claim 1, further comprising an accessory removably coupled with the first service interface and providing an additional function to the appliance.

15. The modular system of claim 14 wherein the accessory comprises one of a water filter, a water purifier, an air purifier, a sensor, a light source, a speaker, a motion detector, a transceiver, a wireless transceiver, a microcontroller, a processor, a microprocessor, a dispenser, a network interface adapter, and a memory.

16. The modular system of claim 1 wherein at least one of the visible surface and the cover comprises a material having a material property of attenuating a radio frequency signal.

17. The modular system of claim 1 wherein the appliance comprises a recess formed in the visible surface and the first service interface is disposed entirely within the recess, and the cover conceals the recess when coupled to the visible surface.

18. The modular system of claim 1 wherein the antenna comprises at least one of a patch antenna, a slot antenna, a microstrip antenna, a printed antenna, a monopole antenna, a dipole antenna, and a wire antenna.
